(19) United States
(12) Patent Application Publication
(10) Pub. No.: US 2025/0226842 A1
(43) Pub. Date: Jul. 10, 2025

(54) ERROR CORRECTION CIRCUIT, MEMORY SYSTEM AND ERROR CORRECTION METHOD

(71) Applicant: Samsung Electronics Co., Ltd., Suwon-si (KR)

(72) Inventors: Myungkyu Lee, Suwon-si (KR); Seongmuk Kang, Suwon-si (KR); Kyomin Sohn, Suwon-si (KR); Kijun Lee, Suwon-si (KR)

(21) Appl. No.: 18/930,158

(22) Filed: Oct. 29, 2024

(30) Foreign Application Priority Data
Jan. 4, 2024 (KR) 10-2024-0001735

(51) Int. Cl. H03M 13/15

(52) U.S. Cl. CPC H03M 13/1525; H03M 13/1515; H03M 13/1575

(57) ABSTRACT

An error correction device includes a syndrome generation circuit configured to output a first syndrome, a second syndrome, a third syndrome, a fourth syndrome, a fifth syndrome, and a sixth syndrome for data, an error location determination circuit configured to determine a coefficient of a first error location polynomial, based on the first syndrome, the second syndrome, and the third syndrome, determine a coefficient of a second error location polynomial, based on the fourth syndrome, the fifth syndrome, and the sixth syndrome, and obtain locations of errors included in the data in units of two consecutive symbols, based on the first error location polynomial and the second error location polynomial, and an error value determination circuit configured to predetermine values of the errors in units of two consecutive symbols, based on the first syndrome and the second syndrome.

### CROSS-REFERENCE TO RELATED APPLICATION

This application is based on and claims priority under 35 U.S.C. § 119 to Korean Patent Application No. 10-2024-0001735, filed on Jan. 4, 2024, in the Korean Intellectual Property Office, the disclosure of which is incorporated by reference herein in its entirety.

### BACKGROUND

The inventive concept relates to a memory device, and more particularly, to an error correction circuit, a memory system, and an error correction method.

Error correction circuits may perform error correction coding (ECC) to correct error bits in information data.

As the communication speed increases and the data throughput increases, the number of error bits in information data may increase. Due to the increase in error bits, the error correction latency required from when an error correction decoder receives information data until when the error correction decoder outputs correction data may increase.

### SUMMARY

The inventive concept provides an error correction decoder including an error correction device correcting an error in units of two consecutive symbols, thereby reducing the error correction latency.

According to some embodiments of the inventive concept, there is provided an error correction device including a syndrome generation circuit configured to receive data and output a first syndrome, a second syndrome, a third syndrome, a fourth syndrome, a fifth syndrome, and a sixth syndrome for the data that are determined by substituting powers of primitive elements of a Galois field into a reception polynomial based on the data. Respective exponents of the powers of respective ones of the primitive elements used to determine the first syndrome, the second syndrome, and the third syndrome sequentially increase, and respective exponents of the powers of respective ones of the primitive elements used to determine the fourth syndrome, the fifth syndrome, and the sixth syndrome sequentially increase. The error correction device includes an error location determination circuit configured to determine a coefficient of a first error location polynomial based on the first syndrome, the second syndrome, and the third syndrome, determine a coefficient of a second error location polynomial based on the fourth syndrome, the fifth syndrome, and the sixth syndrome, and obtain locations of errors included in the data in units of two consecutive symbols based on the first error location polynomial and the second error location polynomial, an error value determination circuit configured to predetermine values of the errors in units of two consecutive symbols, based on the first syndrome and the second syndrome, and an error correction circuit configured to correct the errors included in the data, based on the locations of the errors and the values of the errors.

According to some embodiments of the inventive concept, there is provided a memory system including a memory device including a plurality of memory cells, and a memory controller configured to correct data that has been read from the memory device. The memory controller includes an error correction device. The error correction device includes a syndrome generation circuit configured to receive data and output a first syndrome, a second syndrome, a third syndrome, a fourth syndrome, a fifth syndrome, and a sixth syndrome for the data that are determined by substituting powers of primitive elements of a Galois field into a reception polynomial based on the data. Respective exponents of the powers of respective ones of the primitive elements used to determine the first syndrome, the second syndrome, and the third syndrome sequentially increase, and respective exponents of the powers of respective ones of the primitive elements used to determine the fourth syndrome, the fifth syndrome, and the sixth syndrome sequentially increase. The memory controller includes an error location determination circuit configured to determine a coefficient of a first error location polynomial based on the first syndrome, the second syndrome, and the third syndrome, determine a coefficient of a second error location polynomial based on the fourth syndrome, the fifth syndrome, and the sixth syndrome, and obtain locations of errors included in the data in units of two consecutive symbols, based on the first error location polynomial and the second error location polynomial The memory controller includes an error value determination circuit configured to predetermine values of the errors in units of two consecutive symbols, based on the first syndrome and the second syndrome, and an error correction circuit configured to correct the errors included in the data, based on the locations of the errors and the values of the errors.

According to some embodiments of the inventive concept, there is provided an error correction method including receiving data and outputting a first syndrome, a second syndrome, a third syndrome, a fourth syndrome, a fifth syndrome, and a sixth syndrome for the data that are determined by substituting powers of primitive elements of a Galois field into a reception polynomial based on the data. Respective exponent of the power of respective ones of the primitive elements used to determine the first syndrome, the second syndrome, and the third syndrome sequentially increases, and exponents of the powers of respective ones of the primitive elements used to determine the fourth syndrome, the fifth syndrome, and the sixth syndrome sequentially increase, determining a coefficient of a first error location polynomial based on the first syndrome, the second syndrome, and the third syndrome, determining a coefficient of a second error location polynomial, based on the fourth syndrome, the fifth syndrome, and the sixth syndrome, and obtaining locations of errors included in the data in units of two consecutive symbols based on the first error location polynomial and the second error location polynomial, pre-calculating values of errors in units of two consecutive symbols based on the first syndrome and the second syndrome, and correcting the errors included in the data, based on the locations of the errors and the values of the errors.

### BRIEF DESCRIPTION OF THE DRAWINGS

Embodiments will be more clearly understood from the following detailed description taken in conjunction with the accompanying drawings in which:

FIG. 1 is a block diagram illustrating a memory system according to some embodiments;

FIG. 2 is a block diagram illustrating a method, performed by a memory system, of encoding and decoding data, according to the inventive concept;

FIG. 3 is a block diagram illustrating an example of a decoder shown in FIG. 2;

FIG. 4A is a block diagram illustrating an example of a Reed-Solomon (RS) code decoder shown in FIG. 3;

FIG. 4B is a flowchart illustrating an operation method of the RS code decoder shown in FIG. 3;

FIG. 5 is a block diagram illustrating an example of an error correction device shown in FIG. 3;

FIG. 6A is a block diagram illustrating an example of an error location determination circuit shown in FIG. 5;

FIG. 6B is a block diagram illustrating an example of a sub error location determination circuit shown in FIG. 6A;

FIG. 6C is a block diagram illustrating an example of an error location polynomial generation circuit shown in FIG. 6B;

FIG. 7A is a block diagram illustrating an example of an error value determination circuit shown in FIG. 5;

FIG. 7B is a block diagram illustrating an example of the error value determination circuit shown in FIG. 7A;

FIG. 8 is a flowchart illustrating an error correction method according to a decoder shown in FIG. 3;-

FIG. 9 is a block diagram illustrating another example of a decoder shown in FIG. 2;

FIG. 10 is a block diagram illustrating an example of an error correction device shown in FIG. 9;

FIG. 11 is a flowchart illustrating an error correction method according to the decoder shown in FIG. 9;

FIG. 12 is a diagram illustrating a memory device according to some embodiments;

FIG. 13 is a diagram illustrating a system to which a storage device is applied, according to some embodiments; and

FIG. 14 is a block diagram illustrating an example in which a memory controller is applied to a solid state drive (SSD) system, according to some embodiments.

### DETAILED DESCRIPTION

Hereinafter, various embodiments of the inventive concept will be described with reference to the accompanying drawings.

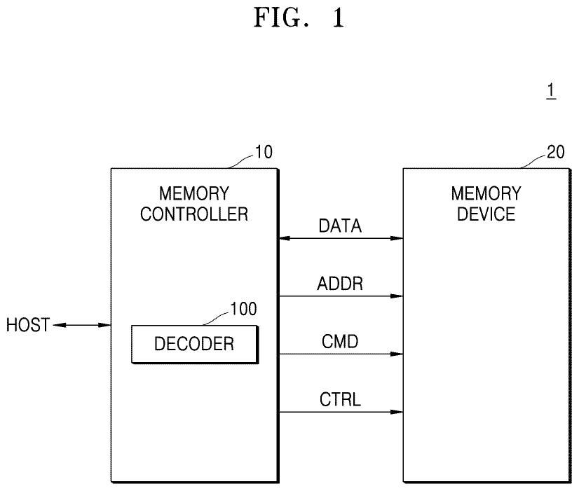

FIG. 1 is a block diagram illustrating a memory system according to some embodiments.

Referring to FIG. 1, a memory system 1 may include a memory controller 10 and a memory device 20. The memory system 1 may also be referred to as a storage device. In addition, the memory system 1 may refer to a computing device, such as an integrated circuit, an electronic device or system, a smartphone, a tablet PC, a computer, a server, a workstation, a portable communication terminal, a personal digital assistant (PDA), a portable multimedia player (PMP), and/or other suitable computers, a virtual machine, or a virtual computing device thereof. The memory system 1 may be a part of components included in a computing system, such as a graphics card. According to some embodiments, the memory system 1 may be implemented as an unbuffered dual in-line memory module (UDIMM), a registered DIMM (RDIMM), a load reduced DIMM (LRDIMM), a fully buffered DIMM (FBDIMM), a small outline DIMM (SODIMM), etc.

The memory device 20 may include a memory cell array including a plurality of memory cells. The memory cell array may include a plurality of word lines, a plurality of bit lines, and a plurality of memory cells formed at points where the word lines and the bit lines cross each other. The memory cells of the memory cell array may be volatile memory cells (e.g., dynamic random access memory (DRAM) cells, static RAM (SRAM) cells, nonvolatile memory cells (e.g., flash memory cells, Resistive RAM (ReRAM) cells, Phase change RAM (PRAM) cells, Magnetic RAM (MRAM) cells, or any other types of memory cells.

In some embodiments, the memory system 1 may be implemented as an embedded or removable memory in an electronic device and, for example, may be implemented in various forms such as an embedded universal flash storage (UFS) memory device, embedded multi-media card (eMMC), solid state drive (SSD), UFS memory card, compact flash (CF) memory, secure digital (SD) memory, Micro Secure Digital (Micro-SD) memory, Mini Secure Digital (Mini-SD) memory, extreme Digital (xD) memory, or memory stick.

The memory controller 10 may control the memory device 20 to read data stored in the memory device 20 or write data to the memory device 20 in response to a write/read request from a host HOST. Specifically, the memory controller 10 may control write, read, and erase operations on the memory device 20 by providing an address ADDR, a command CMD, and a control signal CTRL to the memory device 20. In addition, the data DATA to be stored in the memory device 20 and the data DATA read from the memory device 20 may be transmitted and received between the memory controller 10 and the memory device 20.

The memory controller 10 may include a decoder 100.

The decoder 100 may perform decoding using an error correction code (hereinafter, referred to as ECC) on data read from the memory device 20. The decoder 100 may perform decoding to correct an error in the read data.

That is, the decoder 100 may correct data read from the memory cell array of the memory device 20.

According to some embodiments, the decoder 100 includes an error correction device that corrects errors in units of two consecutive symbols other than a Reed-Solomon (RS) decoder, thereby reducing the time required for RS decoding. Accordingly, the read latency may be improved.

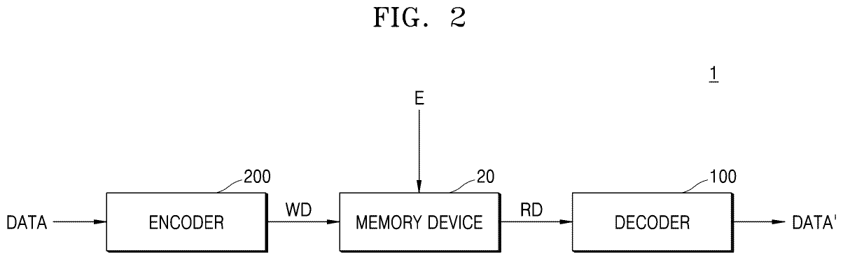

FIG. 2 is a block diagram illustrating a method, performed by a memory system, of encoding and decoding data, according to the inventive concept.

Referring to FIG. 2, the memory system 1 may further include an encoder 200 in addition to the memory device 20 and the decoder 100 shown in FIG. 1. According to some embodiments, the encoder 200 may be included in the memory controller 10 (FIG. 1).

First, when the data DATA is input from the host HOST (see FIG. 1), the input data DATA may be encoded by the encoder 200. At this time, the encoder 200 may perform RS code encoding on the input data DATA. Here, the encoded data may be referred to as an encoded codeword.

That is, the encoder 200 may perform RS code encoding on data to generate a codeword of an RS code. In addition, the encoded data (e.g., codewords of a plurality of RS codes) may be written to the memory device 20 as write data WD.

In addition, when a read command is received, the memory system 1 may read data stored in the memory device 20 as read data RD. At this time, the read data RD may include errors E that occurred for various reasons. For example, the errors E may occur due to a malfunction when the write data WD is programmed or a data loss while the write data WD is stored in the memory device 20. According to some embodiments, the errors E may occur due to a malfunction in a read operation of reading the read data RD.

The decoder 100 may perform RS code decoding on the read data RD to eliminate the errors E. Here, the read data RD may be referred to as a read codeword. A decoding result may be output as corrected data DATA′.

Hereinafter, a method, performed by the encoder 200, of generating a codeword encoded with an RS code is described.

The RS code is a non-binary error correction code, and error correction using the RS code may be performed in unit of a symbol rather than in unit of a bit. Here, the symbol may refer to information represented by a predetermined number of bits.

When one symbol is expressed as m bits, the RS code may be defined by GF(2^{m}), which is a Galois field having the size of 2^{m}. The Galois field is a finite field and has a finite number of elements.

In the finite field GF(2^{m}) having a size of 2^{m}, GF(2^{m})={0, 1, α¹, . . . , α²^{^{m}}⁻²}. That is, GF(2^{m}) may include 2^{m} elements. Here, α may be a primitive element of the Galois field GF(2^{m}).

In addition, 2^{m} symbols, which are all case numbers that m-bits may express, and all 2^{m} elements of GF(2^{m}) may have a one-to-one mapping relationship.

This will be explained assuming the RS code having a total of N symbols. At this time, a decoded RS code may include K data symbols and P parity symbols. The assumed RS code may correct up to P/2 errors. That is, when N=K+P and one symbol is m-bit, the maximum code length of a symbol unit is 2^{m}−1. Here, N, K, and P are positive integers.

Codewords encoded with the RS code may be N-dimensional vectors c₀, c₁, . . . , c_{N-1} obtained from coefficients of a code polynomial c(x). Here, the code polynomial c(x) may be an N-order polynomial for x having no constant term, and the codewords encoded in the RS code may be the N dimensional vectors c₀, c₁, . . . , c_{N-1} obtained from a code polynomial c(x)=c₀x+c₁x²+c₂x³+ . . . +c_{N-1}x^{N}.

In addition, the code polynomial c(x) may be expressed as the product of an information polynomial m(x) and a generative polynomial g(x). In other words, it may be c(x)=m(x)*g(x)

Here, the information polynomial m(x) may correspond to K data symbols and may be a K-order polynomial for x. In addition, it may be a generative polynomial g(x)=Πᵢ₌₀^{P-1}(x+αⁱ), and the generative polynomial g(x) may be a P-order polynomial for x.

When x is an element of the Galois field GF(2^{m}), a value of the generating polynomial g(x) may be 0. In addition, when x is a power of α which is the primitive element of the Galois field GF(2^{m}), the value of the generating polynomial g(x) may be 0. That is, in the generative polynomial g(x), it may be g(α⁰)=0, g(α¹)=0 . . . , g(α^{P-1})=0.

Therefore, because c(x)=m(x)*g(x) and g(α⁰)=0, g(α¹)=0, . . . , g(α^{P-1})=0, it may be c(α⁰)=0, c(α¹)=0, . . . , c(α^{P-1})=0.

At this time, powers of a which are P primitive elements may be substituted into x in the code polynomial c(x)=c₀X+c₁x²+c₂x³+ . . . +c_{N-1}x^{N}, and a result of substituting the powers of Q- which are P primitive elements into the code polynomial c(x) may be expressed as a matrix product as shown in Equation 1 below.

$$[ \begin{matrix}c ( {α}^{0} ) \\ c ( {α}^{1} ) \\ c ( {α}^{2} ) \\ ⋮ \\ c ( {α}^{P - 1} )\end{matrix} ] = [ \begin{matrix}{α}^{0} & {α}^{0} & … & {α}^{0} & … & {α}^{0} \\ {α}^{1} & {α}^{2} & … & {α}^{i} & … & {α}^{N} \\ {α}^{2} & {α}^{4} & … & {α}^{2 i} & … & {α}^{2 N} \\ & & & ⋮ & & \\ {α}^{P - 1} & {α}^{2 ( P - 1 )} & … & {α}^{i ( P - 1 )} & … & {α}^{N ( P - 1 )}\end{matrix} ] [ \begin{matrix}{C}_{0} \\ {C}_{1} \\ {C}_{2} \\ ⋮ \\ {C}_{N - 1}\end{matrix} ] \qquad [ Equation 1 ]$$

Here

$$[ \begin{matrix}{α}^{0} & {α}^{0} & … & {α}^{0} & … & {α}^{0} \\ {α}^{1} & {α}^{2} & … & {α}^{i} & … & {α}^{N} \\ {α}^{2} & {α}^{4} & … & {α}^{2 i} & … & {α}^{2 N} \\ & & & ⋮ & & \\ {α}^{P - 1} & {α}^{2 ( P - 1 )} & … & {α}^{i ( P - 1 )} & … & {α}^{N ( P - 1 )}\end{matrix} ]$$

may denote the primitive element of the Galois field GF(2^{m}).

In addition,

$$[ \begin{matrix}{α}^{0} & {α}^{0} & … & {α}^{0} & … & {α}^{0} \\ {α}^{1} & {α}^{2} & … & {α}^{i} & … & {α}^{N} \\ {α}^{2} & {α}^{4} & … & {α}^{2 i} & … & {α}^{2 N} \\ & & & ⋮ & & \\ {α}^{P - 1} & {α}^{2 ( P - 1 )} & … & {α}^{i ( P - 1 )} & … & {α}^{N ( P - 1 )}\end{matrix} ]$$

may be a matrix that defines rules for generating a parity symbol for the RS code including K data symbols and P parity symbols and having a total of N symbols. The matrix may be referred to as an H matrix.

In addition, columns multiplied by 0th to K−1 coefficients c₀ to cₖ₋₁ of a code polynomial in the H matrix may be defined as H_{K}, columns multiplied by Kth to N−1 coefficients cx to c_{N-1} of the code polynomial in the H matrix may be defined as H_{P}, a K dimensional vector

$$( \begin{matrix}{c}_{0} \\ ⋮ \\ {c}_{K - 1}\end{matrix} )$$

may be defined as C_{K}, and a P-dimensional vector

$$( \begin{matrix}{c}_{K} \\ ⋮ \\ {c}_{N - 1}\end{matrix} )$$

may be defined as C_{P}. At this time, the right side of Equation 1 may be expressed as

$$\begin{matrix}[ {H}_{K} & {H}_{P} ]\end{matrix} [ \begin{matrix}{C}_{K} \\ {C}_{P}\end{matrix} ] .$$

In this case, because it is c(α⁰)=0, c(α¹)=0, . . . c(α^{P-1})=0,

$$\begin{matrix}[ {H}_{K} & {H}_{P} ]\end{matrix} [ \begin{matrix}{C}_{K} \\ {C}_{P}\end{matrix} ] = 0$$

may be satisfied. Therefore, it may be C_{P}=H_{P}⁻¹(H_{K}C_{K}).

That is, the encoder 200 may calculate C_{K} by using K data symbols and may generate a codeword including K data symbols and P parity symbols by using the calculated C_{K} and C_{P}=H_{P}⁻¹(H_{K}C_{K}). Here, the codeword encoded with the RS code may be the N-dimensional vectors c₀, c₁, . . . , c_{N-1} obtained from the coefficients of the code polynomial c(x).

Hereinafter, a method of operating a decoder 300, according to some embodiments, is described.

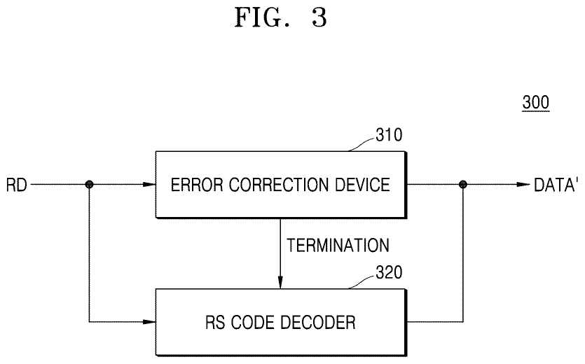

FIG. 3 is a block diagram illustrating an example of a decoder 100 shown in FIG. 2.

Referring to FIG. 3, a decoder 300 may include an error correction device 310 and an RS code decoder 320.

The error correction device 310 and the RS code decoder 320 may receive the data RD read from a memory cell array.

The error correction device 310 may determine locations and sizes of errors included in the data RD in units of two consecutive symbols, and correct the errors included in the data RD based on the determined locations and sizes of errors. The error correction device 310 may output the error corrected data DATA′.

That is, the error correction device 310 may determine the locations and sizes of errors in parallel for each of a plurality of groups including two consecutive symbols without overlapping. For example, when the read data RD includes N symbols, the error correction device 310 may determine in parallel locations and sizes of errors included in 0th and first symbols, locations and sizes of errors included in second and third symbols, and locations and sizes of errors included in N−2 and N−1 symbols.

The RS code decoder 320 may determine locations and sizes of all errors included in the data RD, and correct the errors included in the data RD based on the determined locations and sizes of the errors. The RS code decoder 320 may output the error corrected data DATA′.

That is, the RS code decoder 320 may determine the locations and sizes of the errors included in the 0th to N−1 symbols at one time.

Furthermore, in parallel with an error correction operation of the error correction device 310, an error correction operation of the RS code decoder 320 may be performed. That is, the error correction device 310 and the RS code decoder 320 may simultaneously start the error correction operation.

Since the error correction device 310 determines the locations and sizes of errors in parallel for each of the plurality of groups including two consecutive symbols without overlapping, the error correction device 310 may have less operations than the RS code decoder 320 that needs to determine the locations and sizes of all the errors included in the data RD.

Therefore, the error correction operation of the error correction device 310 may be performed faster than the error correction operation of the RS code decoder 320.

When the error correction operation of the error correction device 310 is successful, because the error correction operation of the RS code decoder 320 does not need to be performed, the error correction device 310 may output, to the RS code decoder 320, a signal TERMINATION indicating termination of the error correction operation of the RS code decoder 320.

That is, when the error correction operation of the error correction device 310 is successful, the corrected data DATA′ may be output by the error correction device 310, and when the error correction operation of the error correction device 310 fails, the corrected data DATA′ may be output by the RS code decoder 320.

Before describing the error correction operation of the error correction device 310, the error correction operation of the RS code decoder 320 is described in detail.

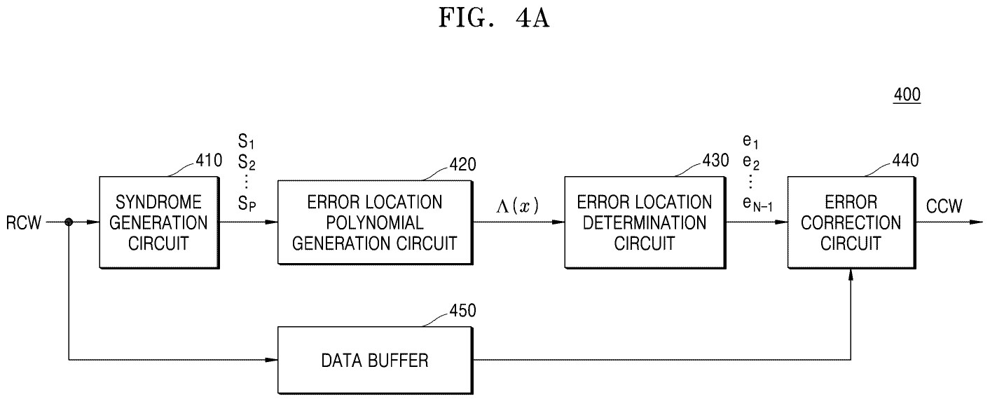

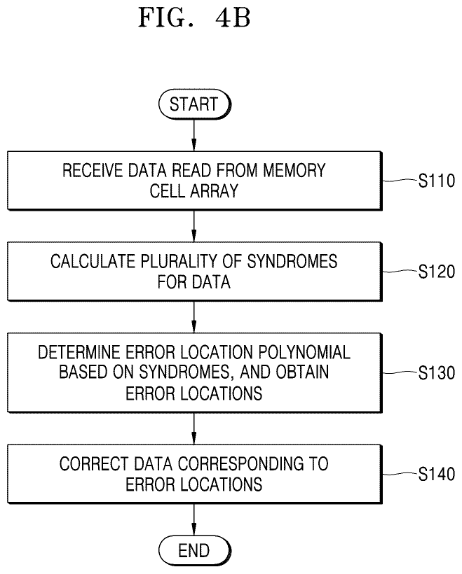

FIG. 4A is a block diagram illustrating an example of an RS code decoder shown in FIG. 3. FIG. 4B is a flowchart illustrating an operation method of the RS code decoder shown in FIG. 3. Hereinafter, the read data RD of FIG. 3 may be referred to as a read codeword RCW.

This will be explained assuming the RS code having a total of N symbols. At this time, a decoded RS code may include K data symbols and P parity symbols. The assumed RS code may correct up to P/2 errors. That is, when N=K+P and one symbol is m-bit, the maximum code length of a symbol unit is 2^{m}−1. Here, N, K, and P are positive integers.

Referring to FIG. 4A, an RS code decoder 400 may include a syndrome generation circuit 410, an error location polynomial generation circuit 420, an error location determination circuit 430, an error correction circuit 440, and a data buffer 450.

The RS code decoder 400 may receive the read codeword RCW and correct errors included in the read codeword RCW. The RS code decoder 400 may output an error corrected codeword CCW.

Data may be the codeword RCW read from the memory cell array. The read codeword RCW may be N-dimensional vectors R₀, R₁, . . . , R_{N-1}. Coefficients of a reception polynomial R(x) may be obtained from the N-dimensional vectors R₀, R₁, . . . , R_{N-1} of the read codeword RCW. Here, the reception polynomial R(x) may be an N-order polynomial for x and may determine coefficients of a reception polynomial R(x)=R₀x+R₁x²+R₂x³+ . . . +R_{N-1}x^{N} from the N-dimensional vectors R₀, R₁, . . . , R_{N-1} of the read codeword RCW.

The error corrected codeword CCW may be the same as the N-dimensional vectors c₀, c₁, . . . , c_{N-1} obtained from the coefficients of the code polynomial c(x) described with reference to FIG. 2.

Here, the code polynomial c(x) may be an N-order polynomial for x having no constant term, and the error corrected codeword CCW may be the same as the N dimensional vectors c₀, c₁, . . . , c_{N-1} obtained from the code polynomial c(x)=c₀X+c₁x²+c₂x³+ . . . +c_{N-1}x^{N}.

In addition, an error polynomial E(x) may be defined as the difference between the receiving polynomial R(x) and the code polynomial c(x). That is, when x is a power of α, which is a primitive element of the Galois field GF(2^{m}), when an error occurs, it may be an error polynomial E(x)=R(x)−c(x), and when there is no error, R(x)=c(x)=0 may be satisfied.

The syndrome generation circuit 410 may receive the read codeword RCW and calculate a plurality of syndromes. The syndrome generation circuit 410 may identify whether an error exists in the read codeword RCW according to values of the calculated syndromes.

For example, values of first to Pth syndromes may be calculated as Equation 2 below.

$$[ \begin{matrix}{S}_{1} \\ {S}_{2} \\ {S}_{3} \\ ⋮ \\ {S}_{P}\end{matrix} ] = [ \begin{matrix}R ( {α}^{0} ) \\ R ( {α}^{1} ) \\ R ( {α}^{2} ) \\ ⋮ \\ R ( {α}^{P - 1} )\end{matrix} ] = [ \begin{matrix}{α}^{0} & {α}^{0} & … & {α}^{0} & … & {α}^{0} \\ {α}^{1} & {α}^{2} & … & {α}^{i} & … & {α}^{N} \\ {α}^{2} & {α}^{4} & … & {α}^{2 i} & … & {α}^{2 N} \\ & & & ⋮ & & \\ {α}^{P - 1} & {α}^{2 ( P - 1 )} & … & {α}^{i ( P - 1 )} & … & {α}^{N ( P - 1 )}\end{matrix} ] [ \begin{matrix}{R}_{0} \\ {R}_{1} \\ {R}_{2} \\ ⋮ \\ {R}_{N - 1}\end{matrix} ] \qquad [ Equation 2 ]$$

Here, Sp denotes the value of Pth syndrome and Ct denotes the primitive element of the Galois field GF(2^{m}).

That is, the values of the first to Pth syndromes may be calculated by sequentially substituting P powers of α into x in the reception polynomial R(x)=R₀x+R₁x²+R₂x³+ . . . +R_{N-1}x^{N}. Here, when x is the power of CL, which is the primitive element of the Galois field GF(2^{m}), when an error occurs, it may be an error polynomial E(x)=R(x)−c(x), and when there is no error, may be satisfied.

When all values of the first to P syndromes are 0, no error may be in the read codeword RCW. When all values of the first to Pth syndromes are not 0, an error may be in the read codeword RCW.

When all values of the first to Pth syndromes are 0, the read codeword RCW temporarily stored in the data buffer 450 may be output to the outside of the RS code decoder 400 without a separate error correction.

When all values of the first to Pth syndromes are not 0, the plurality of syndromes may be transmitted to the error location polynomial generation circuit 420.

The error location polynomial generation circuit 420 may generate an error location polynomial Λ(x) used to search for a location of an error included in the read codeword RCW based on the plurality of syndromes.

The error location polynomial generation circuit 420 may be referred to as a key equation solver. The error location polynomial generation circuit 420 may generate the error location polynomial Λ(x) by using a Berlekamp-Massey algorithm, a Peterson-Gorenstein-Zierler (PGZ) algorithm, a Step-By-Step (SBS) algorithm, a Euclidean algorithm, or a modified Euclidean algorithm. The error location may be obtained by taking a reciprocal of the root of the error location polynomial Λ(x). In some embodiments, the error location may be obtained by taking the reciprocal of the root of the error location polynomial Λ(x) by using a chien-search algorithm.

The error location determination circuit 430 may calculate error locations based on the error location polynomial and output flag signals e₁, e₂, . . . , e_{N-1} indicating the error locations according to a calculation result. The error location determination circuit 430 may transmit the flag signals e₁, e₂, . . . , e_{N-1} indicating the error locations to the error correction circuit 440.

The error correction circuit 440 may correct errors of the read codeword RCW received from the data buffer 450 based on the flag signals e₁, e₂, . . . , e_{N-1} indicating the error locations, and output the error corrected codeword CCW.

In some embodiments, the error correction circuit 440 may identify a symbol in which an error has occurred among a plurality of symbols included in the codeword based on the flag signals e₁, e₂, . . . , e_{N-1} indicating the error locations and may calculate an error value of the symbol in which the error has occurred by using a Forney algorithm, etc. The error correction circuit 440 may output the error corrected codeword CCW, based on the read codeword RCW provided from the data buffer 450, the error locations, and the error values.

The data buffer 450 may receive the read codeword RCW, temporarily store the read codeword RCW, and provide the read codeword RCW to the error correction circuit 440.

In some embodiments, when the values of the flag signals e₁, e₂, . . . , e_{N-1} are all 0, the error correction circuit 440 may output the read codeword RCW received from the data buffer 450 as is without a separate correction.

In some embodiments, when the values of the flag signals e₁, e₂, . . . , e_{N-1} are all 0, the error correction circuit 440 may output the read codeword RCW received from the data buffer 450 as it is without a separate correction.

In some embodiments, when the values of the flag signals e₁, e₂, . . . , e_{N-1} are not all 0, the error correction circuit 440 may correct errors of the read codeword RCW received from the data buffer 450, based on the error locations and the error values, and output the error corrected codeword CCW.

Referring to FIGS. 4A and 4B, in operation S110, the RS code decoder 400 may receive the codeword RCW read from a memory cell array. The read codeword RCW may include a plurality of symbols. For example, the read codeword RCW may include N symbols, and the N symbols decoded by the RS code decoder 400 may include K data symbols and P parity symbols.

In operation S120, the syndrome generation circuit 410 may calculate the plurality of syndromes for the read codeword RCW. The syndromes may be data indicating whether an error exists in data. When values of all syndromes are 0, no error may be in the data. When the values of all syndromes are not 0, errors may be in the data.

In operation S130, the error location polynomial generation circuit 420 may determine the error location polynomial Λ(x) based on the plurality of syndromes, and the error location determination circuit 430 may obtain error locations. The error locations may be obtained by taking the reciprocal of the root of the error location polynomial Λ(x). The error location determination circuit 430 may output the flag signals e₁, e₂, . . . , e_{N-1} indicating the error locations.

In operation S140, the error correction circuit 440 may identify a symbol in which an error has occurred among the plurality of symbols included in the read codeword RCW based on the flag signals e₁, e₂, . . . , e_{N-1} indicating the error locations and may calculate an error value of the symbol in which the error has occurred by using the Forney algorithm, etc. The error correction circuit 440 may output the error corrected codeword CCW, based on the read codeword RCW provided from the data buffer 450, the error locations, and the error values.

In addition, the RS code decoder 400 requires the most operations in operation S130 among operations S110 to S140. For example, when the Berlekamp-Massey algorithm is used in operation S130, the RS code decoder 400 performs a predetermined number of repetitive operations (e.g., the number P of parity symbols) regardless of the number of errors that have actually occurred, and the amount of operations performed per repetitive operation is also large. In addition, when the PGZ algorithm is used in operation S130, matrix reverse transformation and matrix multiplication are required, which has high complexity, and this complexity increases the time required for RS decoding.

According to some embodiments, the decoder 300 includes the error correction device 310 (FIG. 3) that corrects errors in units of two consecutive symbols in addition to the RS code decoder 400, thereby reducing the time required for RS decoding. Accordingly, the read latency may be improved.

Hereinafter, an error correction operation of the error correction device 310 is described in detail.

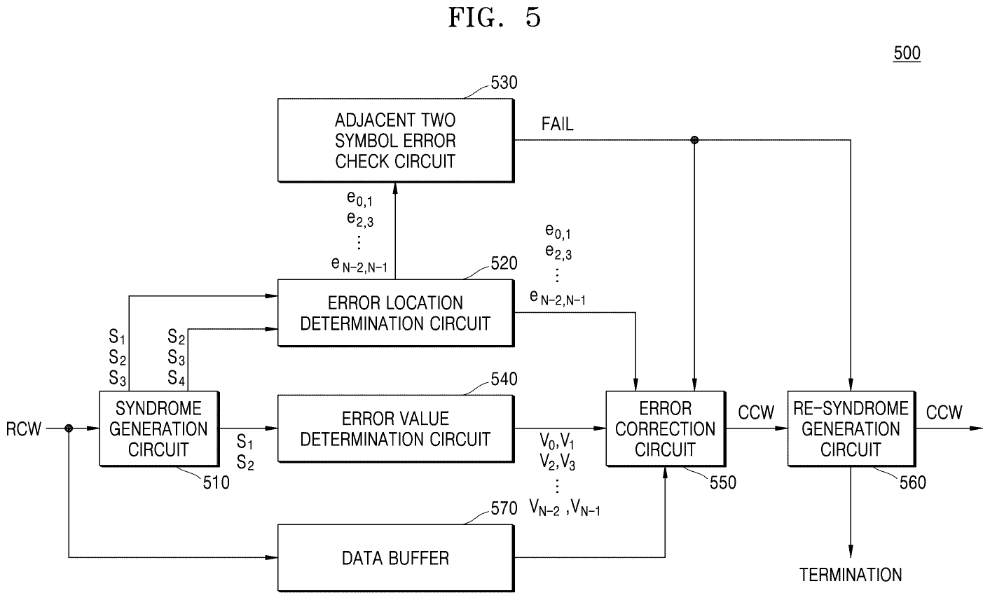

FIG. 5 is a block diagram illustrating an example of an error correction device 310 shown in FIG. 3.

Referring to FIG. 5, an error correction device 500 may include a syndrome generation circuit 510, an error location determination circuit 520, an adjacent two-symbol error check circuit 530, an error value determination circuit 540, an error correction circuit 550, a re-syndrome generation circuit 560, and a data buffer 570.

The syndrome generation circuit 510 may receive data and output first to sixth syndromes with respect to the data. Here, the first to sixth syndromes may be calculated by substituting powers of the primitive elements α of the Galois field GF(2^{m}) into the reception polynomial R(x) based on the data, an exponent of the power of each of the primitive elements used to calculate the first to third syndromes may sequentially increase, and an exponent of the power of each of the primitive elements used to calculate the fourth to sixth syndromes may sequentially increase. For example, the exponent of the power of each of the primitive elements used to calculate the first to third syndromes may sequentially increase by 1, and the exponent of the power of each of the primitive elements used to calculate the fourth to sixth syndromes may sequentially increase by 1.

In addition, for example, the data may be the codeword RCW read from a memory cell array. The read codeword RCW may be the N-dimensional vectors R₀, R₁, . . . , R_{N-1}. Coefficients of the reception polynomial R(x) may be obtained from the N-dimensional vectors R₀, R₁, . . . , R_{N-1} of the read codeword RCW. Here, the reception polynomial R(x) may be an N-order polynomial for x and may determine coefficients of the reception polynomial R(x)=R₀x+R₁x²+R₂x³+ . . . +R_{N-1}x^{N} from the N-dimensional vectors R₀, R₁, . . . , R_{N-1} of the read codeword RCW. The syndrome generation circuit 510 may calculate the syndromes by substituting the powers of the primitive elements α of the Galois field GF(2^{m}) into the reception polynomial R(x)=R₀x+R₁x²+R₂x³+ . . . +R_{N-1}x^{N} in which the coefficients are determined based on the data.

Referring to FIG. 5, in some embodiments, a second syndrome S₂ may be the same as a fourth syndrome S₂ and a third syndrome S₃ may be the same as a fifth syndrome S₃. That is, the exponent of power of each primitive element C used to calculate a first syndrome S₁, the second syndrome S₂, the third syndrome S₃, and a sixth syndrome S₄ may sequentially increase.

For example, when the first syndrome S₁ is R(α⁰), the second syndrome S₂ may be R(α¹) and the third syndrome S₃ may be R(α²). In addition, when the fourth syndrome S₂ is R(α¹), the fifth syndrome S₃ may be R(α²) and the sixth syndrome S₄ may be R(α³).

However, the inventive concept is not limited thereto, and unlike FIG. 5, a second syndrome may be different from a fourth syndrome and a third syndrome may be different from a fifth syndrome.

The syndrome generation circuit 510 may provide the calculated syndromes to the error location determination circuit 520 and the error value determination circuit 540. Referring to FIG. 5, the syndrome generation circuit 510 may provide the first syndrome S₁, the second syndrome S₂, the third syndrome S₃, the fourth syndrome S₂, the fifth syndrome S₃, and the sixth syndrome S₄ to the error location determination circuit 520 and may provide the first syndrome S₁ and the second syndrome S₂ to the error value determination circuit 540.

The error location determination circuit 520 may determine a coefficient of a first error location polynomial, based on the first syndrome S₁, the second syndrome S₂, and the third syndrome S₃, and determine a coefficient of a second error location polynomial, based on the fourth syndrome S₂, the fifth syndrome S₃, and the sixth syndrome S₄. In addition, the error location determination circuit 520 may obtain locations of errors included in the data in units of two consecutive symbols, based on the first error location polynomial and the second error location polynomial.

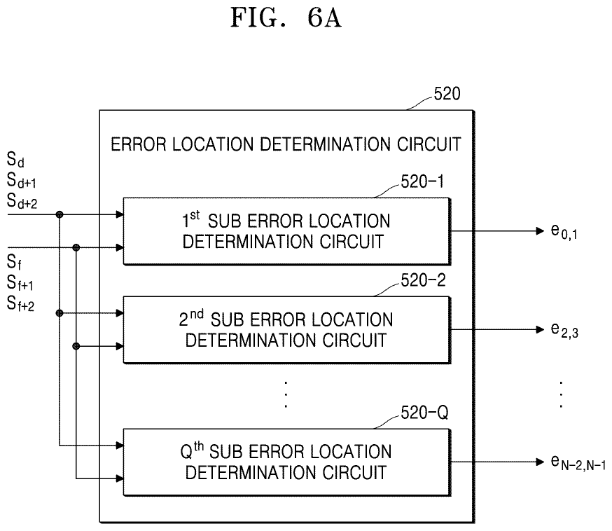

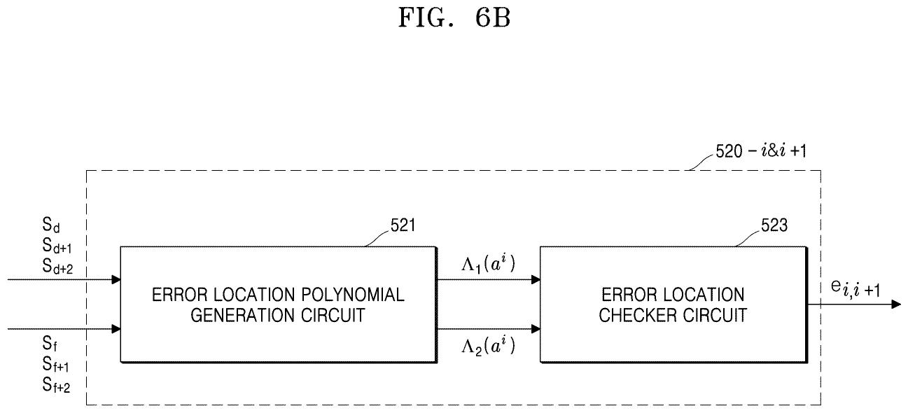

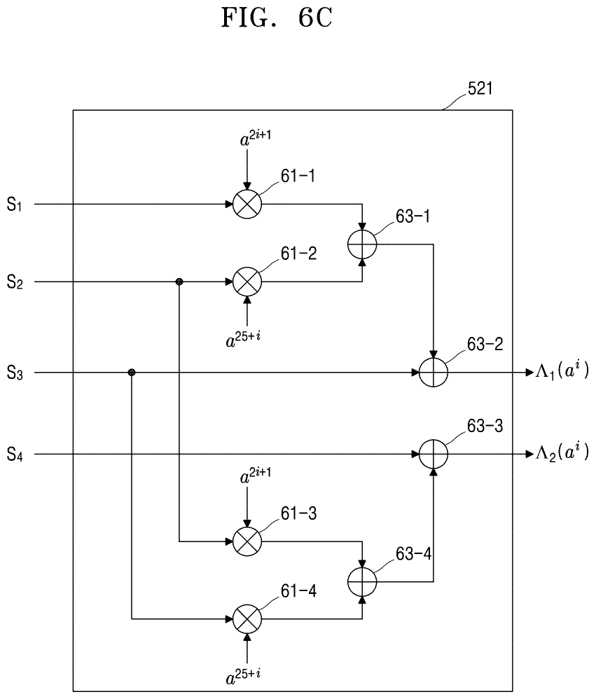

A method, performed by the error location determination circuit 520, of obtaining the locations of the errors included in the data in units of two consecutive symbols is described in detail with reference to FIGS. 6A, 6B, and 6C.

FIG. 6A is a block diagram illustrating an example of an error location determination circuit shown in FIG. 5.

The error location determination circuit 520 may include a plurality of sub error location determination circuits. The plurality of sub error location determination circuits may receive first to sixth syndromes, and each of the plurality of sub error location determination circuits may output an error flag signal indicating whether there are errors in two consecutive symbols. Here, each of the plurality of sub error location determination circuits may match two consecutive symbols without overlapping, and each of the plurality of sub error location determination circuits may output an error flag signal indicating whether there are errors in the two matching symbols.

That is, the error location determination circuit 520 may in parallel determine whether there are errors in each of a plurality of groups including two consecutive symbols without overlapping.

Referring to FIG. 6A, the error location determination circuit 520 may include first to Qth sub error location determination circuits 520-1 to 520-Q. Here, N denotes the total number of symbols included in the read codeword RCW and may be a positive integer and an even number. Also, Q may be (N−2)/2.

The first sub error location determination circuit 520-1 may receive a first syndrome S_{d}, a second syndrome S_{d+1}, a third syndrome S_{d+2}, a fourth syndrome Sf, a fifth syndrome S_{f+1}, and a sixth syndrome S_{f+2}, and output a 0&1 error flag signal e_{0,1} indicating whether there are errors in a 0th symbol and a first symbol. The second sub error location determination circuit 520-2 may receive the first syndrome S_{d}, the second syndrome S_{d+1}, the third syndrome S_{d+2}, the fourth syndrome S_{f}, the fifth syndrome S_{f+1}, and the sixth syndrome S_{f+2} and may output a 2&3 error flag signal e_{2,3} indicating whether there are errors in a second symbol and a third symbol. The Qth sub error location determination circuit 520-Q may receive the first syndrome S_{d}, the second syndrome S_{d+1}, the third syndrome S_{d+2}, the fourth syndrome S_{f}, the fifth syndrome S_{f+1}, and the sixth syndrome S_{f+2} and may output an N−2&N−1 error flag signal e_{N-2,N-1} indicating whether there are errors in an N−2 symbol and an N−1 symbol.

In some embodiments, when errors are in in the two consecutive symbols, each of the sub error location determination circuits may output an error flag signal indicating whether there are errors in the two consecutive symbols such that a value of the error flag signal is 1. When there is no error in the two consecutive symbols, each of the sub error location determination circuits may output an error flag signal indicating whether there are errors in the two consecutive symbols such that a value of the error flag signal is 0.

For example, when there is no error in 0th and first symbols, the first sub error location determination circuit 520-1 may output the 0&1 error flag signal e_{0,1} indicating 0. In addition, when there are errors in second and third symbols, the second sub error location determination circuit 520-2 may output the 2&3 error flag signal e_{2,3} indicating 1.

FIG. 6B is a block diagram illustrating an example of a sub error location determination circuit shown in FIG. 6A. FIG. 6B is a block diagram illustrating an i/2+1 sub error location determination circuit determining whether there are errors in an i-th symbol and an i+1 symbol. Here, i may be one of 0, 2, . . . , and/or N−2. For convenience, the i/2+1 sub error location determination circuit is referred to as an i&i+1 sub error location determination circuit 520-i&i+1.

The first to Qth sub error location determination circuits 520-1 to 520-Q may have the same configuration. Therefore, hereinafter, the configuration and operation of the i&i+1 sub error location determination circuit 520-i&i+1 determining whether the i-th symbol and the i+1 symbol include errors shown in FIG. 6B are described.

The i&i+1 sub error location determination circuit 520-i&i+1 may receive the first syndrome S_{d}, the second syndrome S_{d+1}, the third syndrome S_{d+2}, the fourth syndrome S_{f}, the fifth syndrome S_{f+1}, and the sixth syndrome S_{f+2} and may output an i&i+1 error flag signal e_{i,i+1} indicating whether there are errors in the i-th symbol and the i+1 symbol.

The i&i+1 sub error location determination circuit 520-i&i+1 may include an error location polynomial generation circuit 521 and an error location checker circuit 523.

The error location polynomial generation circuit 521 may receive the first syndrome S_{d}, the second syndrome S_{d+1}, the third syndrome S_{d+2}, the fourth syndrome S_{f}, the fifth syndrome S_{f+1}, and the sixth syndrome S_{f+2}. In addition, the error location polynomial generation circuit 521 may determine a coefficient of a first error location polynomial, based on the first syndrome S_{d}, the second syndrome S_{d+1}, and the third syndrome S_{d+2}. In addition, the error location polynomial generation circuit 521 may determine a coefficient of a second error location polynomial, based on the fourth syndrome S_{f}, the fifth syndrome S_{f+1}, and the sixth syndrome S_{f+2}.

In some embodiments, the error location polynomial generation circuit 521 may determine the coefficient of the first error location polynomial based on Equation 3 below. In addition, the error location polynomial generation circuit 521 may determine the coefficient of the second error location polynomial based on Equation 4 below.

$${Λ}_{1} ( {α}^{i} ) = {S}_{d} ( α * {α}^{2 i} ) + {S}_{d + 1} ( α + 1 ) {α}^{i} + {S}_{d + 2} \qquad [ Equation 3 ]$$

$${Λ}_{2} ( {α}^{i} ) = {S}_{f} ( α * {α}^{2 i} ) + {S}_{f + 1} ( α + 1 ) {α}^{i} + {S}_{f + 2} \qquad [ Equation 4 ]$$

Here, α denotes the primitive element of the Galois field GF(2^{m}), Λ₁(αⁱ) denotes the first error location polynomial, Λ₂(αⁱ) denotes the second error location polynomial, S_{d}, S_{d+1}, S_{d+2} respectively denote the first to third syndromes, S_{f}, S_{f+1}, and S_{f+2} respectively denote the fourth to sixth syndromes, and d and f are positive integers and may be different from each other.

In addition, in some embodiments, the second syndrome may be the same as the fourth syndrome, the third syndrome may be the same as the fifth syndrome, and an exponent of power of each of primitive elements used to calculate the first syndrome, the second syndrome, the third syndrome, and the sixth syndrome may sequentially increase by 1.

At this time, the error location polynomial generation circuit 521 may determine the coefficient of the first error location polynomial based on Equation 5 below. In addition, the error location polynomial generation circuit 521 may determine the coefficient of the second error location polynomial based on Equation 6 below. For example, d may be 1 and f may be 2.

$${Λ}_{1} ( {α}^{i} ) = {S}_{1} ( α * {α}^{2 i} ) + {S}_{2} ( α + 1 ) {α}^{i} + {S}_{3} \qquad [ Equation 5 ]$$

$${Λ}_{2} ( {α}^{i} ) = {S}_{3} ( α * {α}^{2 i} ) + {S}_{3} ( α + 1 ) {α}^{i} + {S}_{4} \qquad [ Equation 6 ]$$

Here, α may denote the primitive element of the Galois field GF(2^{m}), Λ₁(αⁱ) may denote the first error location polynomial, Λ₂(αⁱ) may denote the second error location polynomial, S₁ may denote the first syndrome, S₂ may denote the second syndrome, S₃ may denote the third syndrome, and S₄ may denote the sixth syndrome.

With respect to Equations 5 and 6, it is assumed that errors are included in the i-th symbol and the i+1 symbol, which are consecutive symbols, an error value of the i-th symbol is defined as vᵢ, and an error value of the i+1 symbol is defined as vᵢ₊₁.

In this case, the first syndrome S₁ satisfies S₁=R(α⁰)=c(α⁰)+E(α⁰)=vᵢ(α⁰)′+vᵢ₊₁(α⁰)^{t+1}, the second syndrome S₂ satisfies S₂=R(α¹)=c(α¹)+E(α¹)=vᵢ(α¹)′+vᵢ₊₁(α¹)^{t+1}, and the third syndrome S₃ satisfies S₃=R(α²)=c(α²)+ε(α²)=vᵢ(α²)′+vᵢ₊₁(α²)^{t+1}. When the error value vᵢ of the i-th symbol and the error value vᵢ₊₁ of the i+1 symbol are erased using the first syndrome S₁, the second syndrome S₂, and the third syndrome S₃, Λ₁(αⁱ)=0 may be derived. Similarly, when the error value vᵢ of the i-th symbol and the error value vᵢ₊₁ of the i+1 symbol are erased using the second syndrome S₂, the third syndrome S₃, and the fourth syndrome S₄, Λ₂(αⁱ)=0 may be derived.

Because Λ₁(αⁱ)=0 and Λ₂(αⁱ)=0 are quadratic equations for αⁱ, errors may be included in the i-th symbol and the i+1 symbol when there is αⁱ (i.e., a common root) satisfying both Λ₁(αⁱ)=0 and Λ₂(αⁱ)=0.

The error location polynomial generation circuit 521 may provide the first error location polynomial Λ₁(αⁱ) and the second error location polynomial Λ₂(αⁱ) to the error location checker circuit 523.

The error location checker circuit 523 may output the i&i+1 error flag signal e_{i,i+1} indicating whether there are errors in the i-th symbol and the i+lth symbol based on the first error location polynomial Λ₁(αⁱ) and the second error location polynomial Λ₂(αⁱ).

In some embodiments, the error location checker circuit 523 may output the i&i+1 error flag signal e_{i,i+1} indicating that “errors are included in the i-th symbol and the i+1 symbol” when there is an exponent i satisfying Λ₁(αⁱ)=0 and Λ₂(αⁱ)=0. In addition, the error location checker circuit 523 may output the i&i+1 error flag signal e_{i,i+1} indicating that “there are no errors in the i-th symbol and the i+1 symbol” when there is no exponent i satisfying Λ₁(αⁱ)=0 and Λ₂(αⁱ)=0.

For example, the error location checker circuit 523 may output the error flag signal e_{i,i+1} indicating 1 when there is exponent i satisfying Λ₁(αⁱ)=0 and Λ₂(αⁱ)=0. In addition, the error location checker circuit 523 may output the i&i+1 error flag signal e_{i,i+1} indicating 0 when there is no exponent i satisfying Λ₁(αⁱ)=0 and Λ₂(αⁱ)=0.

In some embodiments, the first error location polynomial and the second error location polynomial may be polynomials related to a power αⁱ of the primitive element of the Galois field having the exponent i, and the error location determination circuit 520 may output the i&i+1 error flag signal e_{i,i+1} indicating that “errors are included in the i-th symbol and the i+1 symbol” when there is the exponent i that determines a value of the first error location polynomial Λ₁(αⁱ) and a value of the second error location polynomial Λ₂(αⁱ) to be 0.

FIG. 6C is a block diagram illustrating an example of an error location polynomial generation circuit shown in FIG. 6B. FIG. 6C is a block diagram illustrating the error location polynomial generation circuit 521 included in the i&i+1 sub error location determination circuit 520-i&i+1. Here, i may be one of 0, 2, . . . , and/or N−2.

In some embodiments, in the Galois field GF(2⁸) defined by the primitive polynomial p(x)=1+x²+x³+x⁴+x⁸, α+1=α²⁵ may be satisfied. Here, m above may be 8. That is, in the finite element GF(2⁸) having a size of 2⁸, it may be GF(2⁸)={0, 1, α¹, . . . , α²⁵⁴}. 256 symbols, which are all case numbers that an 8-bit symbol may express, and all 156 elements of GF(2⁸) may have a one-to-one mapping relationship.

Error location polynomial generation circuits included in the first to Qth sub error location determination circuits 520-1 to 520-Q may have the same configuration. Therefore, hereinafter, the configuration and operation of the error location polynomial generation circuit 521 included in the i&i+1 sub error location determination circuit 520-i&i+1 determining whether the i-th symbol and the i+1 symbol include errors shown in FIG. 6C will be described.

In this case, the second syndrome may be the same as the fourth syndrome, the third syndrome may be the same as the fifth syndrome, and an exponent of power of each of primitive elements used to calculate the first syndrome, the second syndrome, the third syndrome, and the sixth syndrome may sequentially increase by 1.

Referring to FIG. 6C, the error location polynomial generation circuit 521 may include first, second, third, and fourth multipliers 61-1, 61-2, 61-3, 61-4 and first, second, third, and fourth summers 63-1, 63-2, 63-3, and 63-4.

As described above, because it is α+1=α²⁵, the first error location polynomial may be expressed as Λ₁(αⁱ)=S₁α²ⁱ⁺¹+S₂α²⁵⁺ⁱ+S₃ and the second error location polynomial may be expressed as Λ₂(αⁱ)=S₂α²ⁱ⁺¹+S₃α²⁵⁺ⁱ+S₄.

Accordingly, the error location polynomial generation circuit 521 may receive the first syndrome S₁, the second syndrome S₂, the third syndrome S₃, and, as shown in FIG. 6C, a sixth syndrome S₄ and may output the first error location polynomial Λ₁(αⁱ) and the second error location polynomial Λ₂(αⁱ) by using first to fourth multipliers 61-1, 61-2, 61-3, 61-4 and first, second, third, and fourth summers 63-1, 63-2, 63-3, and 63-4.

For example, when i=2, the error location polynomial generation circuit 521 included in the 2&3 sub error location determination circuit corresponding to the second sub error location determination circuit 520-2 shown in FIG. 6A may output the first error location polynomial Λ₁(α²)=S₁α⁵+S₂α²⁷+S₃ and Λ₁(αⁱ) and the second error location polynomial Λ₂(α²)=S₂α⁵+S₃α²⁷+S₄ to the error location checker circuit 523 included in the 2&3 sub error location determination circuit.

When the value of the first error location polynomial Λ₁(α²)=S₁α⁵+S₂α²⁷+S₃ and the values of Λ₁(αⁱ) and the second error location polynomial Λ₂(α²)=S₂α⁵+S₃α²⁷+S₄ are 0, the error location checker circuit 523 may output an error flag signal e_{2,3} indicating that “there are errors are in the second symbol and the third symbol”.

When the value of the first error location polynomial Λ₁(α²)=S₁α⁵+S₂α²⁷+S₃ and the values of Λ₁(αⁱ) and the second error location polynomial Λ₂(α²)=S₂α⁵+S₃α²⁷+S₄ are not 0, the error location checker circuit 523 may output the error flag signal e_{2,3} indicating that “there are errors in the second symbol and the third symbol”.

Referring back to FIG. 5, the error location determination circuit 520 may obtain locations of the errors included in the data in units of two consecutive symbols according to some embodiments described with reference to FIGS. 6A, 6B, and 6C.

That is, the error location determination circuit 520 may output an error flag signal indicating whether two consecutive symbols include errors, and the error location determination circuit 520 may output an error flag signal for each of a plurality of groups including two consecutive symbols without overlapping.

Referring to FIG. 5, the error location determination circuit 520 may output 0&1 to N−2&N−1 error flag signals e_{0,1}˜e_{N-2,N-1}. The error location determination circuit 520 may provide the 0&1 to N−2&N−1 error flag signals e_{0,1}˜e_{N-2,N-1} to the adjacent two-symbol error check circuit 530.

The adjacent two-symbol error check circuit 530 may receive a plurality of error flag signals and check whether errors have occurred in two actually consecutive symbols.

When errors occur in two actually consecutive symbols, only one of the 0&1 to N−2&N−1 error flag signals e_{0,1}˜e_{N-2,N-1} needs to indicate 1, and the remaining error flag signals need to indicate 0.

That is, when all error flag signals indicate 0, it may correspond to a case where the error location determination circuit 520 may not find location of the errors. When errors are included in the data but do not occur in two consecutive symbols, all error flag signals may have 0.

When the 0&1 to N−2&N−1 error flag signals e_{0,1}˜e_{N-2,N-1} all indicate 0, the adjacent two-symbol error check circuit 530 may output a fail signal FAIL to the error correction circuit 550 and the re-syndrome generation circuit 560 to terminate a decoding operation. At this time, the error correction circuit 550 and the re-syndrome generation circuit 560 may terminate the decoding operation in response to the fail signal FAIL.

The error value determination circuit 540 may pre-calculate values of errors that data may have in units of two consecutive symbols based on two syndromes. In addition, the error value determination circuit 540 may provide the pre-calculated values of errors to the error correction circuit 550.

Referring to FIG. 5, the error value determination circuit 540 may pre-calculate the values of errors that data may have in units of two consecutive symbols based on the first syndrome S₁ and the second syndrome S₂, and may provide 0th to N−1 error value signals v₀˜v_{N-1} indicating the pre-calculated values of errors to the error correction circuit 550.

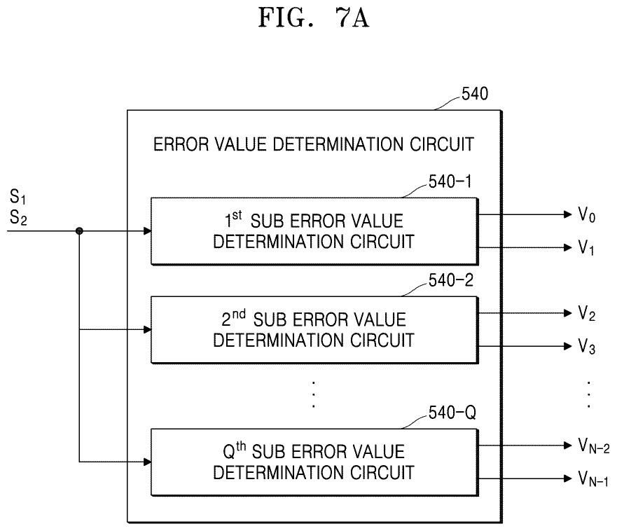

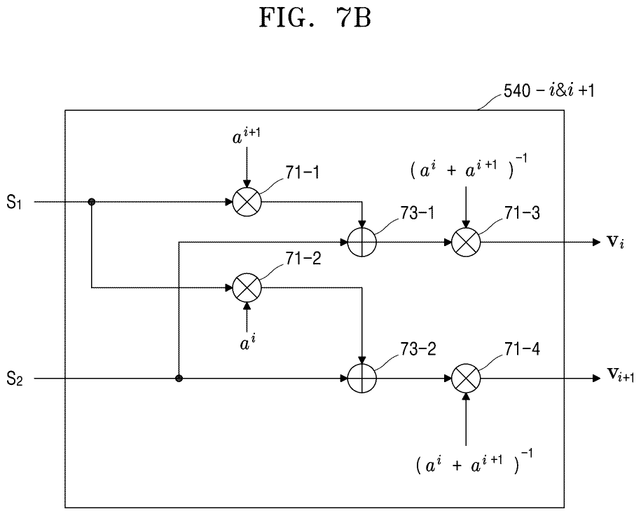

A method, performed by the error value determination circuit 540, of pre-calculating values of errors that data may have in units of two consecutive symbols will be described in detail with reference to FIGS. 7A and 7B.

FIG. 7A is a block diagram illustrating an example of an error value determination circuit shown in FIG. 5. FIG. 7B is a block diagram illustrating an example of an error value determination circuit shown in FIG. 7A.

The error value determination circuit 540 may include a plurality of sub error value determination circuits. The error value determination circuit 540 may output two error values in units of two consecutive symbols by using two syndromes under the assumption that errors are included in consecutive symbols.

Each of the plurality of sub error value determination circuits may receive a first syndrome and a second syndrome, and may output two error value signals indicating error values for two consecutive symbols. Here, each of the plurality of sub error value determination circuits may match two consecutive symbols without overlapping, and may output two error value signals indicating error values for the two matching symbols.

That is, the error value determination circuit 540 may determine values of errors in parallel assuming that an error has occurred for each of a plurality of groups including two consecutive symbols without overlapping.

Referring to FIG. 7A, the error value determination circuit 540 may include first to Qth sub error value determination circuits 540-1 to 540-Q. Here, N denotes the total number of symbols included in the read codeword RCW and may be a positive integer and an even number. Also, Q may be (N−2)/2.

The first sub error value determination circuit 540-1 may receive the first syndrome S₁ and the second syndrome S₂, and output a 0th error value signal V₀ indicating the magnitude of an error for a 0th symbol and a first error value signal V₁ indicating the magnitude of an error for a first symbol. The second sub error value determination circuit 540-2 may receive the first syndrome S₁ and the second syndrome S₂, and output a second error value signal V₂ indicating the magnitude of an error for a second symbol, and a third error value signal indicating the magnitude of an error for a third symbol. The Qth sub error value determination circuit 540-Q may receive the first syndrome S₁ and the second syndrome S₂, and output an N−2 error value signal V_{N-2} indicating the magnitude of an error for an N−2 symbol and an N−1 error value signal V_{N-1} indicating the magnitude of an error for an N−1 symbol.

An i/2+1 sub error value determination circuit outputting an i+1th error value signal vᵢ indicating the magnitude of an error for an i+1 symbol and an i+1 error value signal vᵢ₊₁ indicating the magnitude of an error for an i+1 symbol will be described. Here, i may be one of 0, 2, . . . , and/or N−2. For convenience, the i/2+1 sub error value determination circuit is referred to as an i&i+1 sub error value determination circuit 540-i&i+1.

It is assumed that errors are included in the i-th symbol and the i+1 symbol, which are consecutive symbols, an error value of the i-th symbol is defined as vᵢ, and an error value of the i+1 symbol is defined as vᵢ₊₁.

When the first syndrome S₁ and the second syndrome S₂ are calculated by substituting α⁰ and α¹ with x in the reception polynomial R(x)=R₀x+R₁x²+R₂x³+ . . . +R_{N-1}x^{N}, Equation 7 below is satisfied.

$$\begin{matrix}{S}_{1} = {v}_{i} + {v}_{i + 1} \\ {S}_{2} = {v}_{i} {α}^{i} + {v}_{i + 1} {α}^{i + 1}\end{matrix} \qquad [ Equation 7 ]$$

Here, α denotes the primitive element of the Galois field GF(2^{m}), S₁ denotes the first syndrome, S₂ denotes the second syndrome, vᵢ denotes the error value of the i-th symbol, and vᵢ₊₁ denotes the error value of the i+1 symbol.

That is, because the first syndrome S₁ satisfies S₁=R(α⁰)=c(α⁰)+E(α⁰), the sum of a code polynomial and an error polynomial satisfies c(α⁰)+E(α⁰)=(c₀α⁰+c₁(α⁰)²+c₂(α⁰)³+ . . . +cₙ₋ₜ(α⁰)+vᵢ(α⁰)+vᵢ₊₁(α⁰)ⁱ⁺¹, and a right curly bracket term satisfies 0, Equation 7 may be derived. Similarly, because the second syndrome S₂ satisfies S₂=R(α¹)=c(α¹)+E(α¹) the sum of the code polynomial and the error polynomial satisfies c(α¹)+E(α¹)=(c₀α¹+c₁(α¹)²+c₂(α¹)³+ . . . +cₙ₋ₜ(α¹)+vᵢ(α¹)+vᵢ₊₁(α¹)ⁱ⁺¹, and the right curly bracket term satisfies 0, Equation 7 may be derived.

The error value vᵢ of the i-th symbol and the error value vᵢ₊₁ of the i+1 symbol of Equation 7 may be summarized as in Equation 8 below.

$$\begin{matrix}{v}_{i} = \frac{{S}_{1} {α}^{i + 1} + {S}_{2}}{{α}^{i} + {α}^{i + 1}} \\ {v}_{i + 1} = \frac{{S}_{1} {α}^{i} + {S}_{2}}{{α}^{i} + {α}^{i + 1}}\end{matrix} \qquad [ Equation 8 ]$$

Here, α denotes the primitive element of the Galois field GF(2^{m}), S₁ denotes the first syndrome, S₂ denotes the second syndrome, vᵢ denotes the error value of the i-th symbol, and vᵢ₊₁ denotes the error value of the i+1 symbol.

That is, the i&i+1 sub error value determination circuit 540-i&i+1 may output the i-th error value signal vᵢ indicating the magnitude of the error for the i-th symbol and the i+1th error value signal Vᵢ₊₁ indicating the magnitude of the error for the i+1 symbol based on the first syndrome S₁, the second syndrome S₂, and Equation 8 described above.

FIG. 7B is a block diagram illustrating the i&i+1 sub error value determination circuit 540-i&i+1. Here, i may be one of 0, 2, . . . , and/or N−2. The first to Qth sub error value determination circuits 540-1 to 540-Q may have the same configuration. Therefore, hereinafter, the configuration and operation of the i&i+1 sub error value determination circuit 540-i&i+1 outputting the error values of the i-th symbol and the i+1 symbol shown in FIG. 7B will be described.

Referring to FIG. 7B, the i&i+1 sub error value determination circuit 540-i&i+1 may include first, second, third, and fourth multipliers 71-1, 71-2, 71-3, and 71-4, and first and second summers 73-1 and 73-2.

The i&i+1 sub error value determination circuit 540-i&i+1 may receive the first syndrome Si and the second syndrome S₂, and output the i+1 error value signal vᵢ indicating the magnitude of the error for the i-th symbol and the i+1th error value signal vᵢ₊₁ indicating the magnitude of the error for the i+1 symbol by using the first, second, third, and fourth multipliers 71-1, 71-2, 71-3, and 71-4 and the first and second adders 73-1 and 73-2, as shown in FIG. 7B.

For example, when i=2, the 2&3 sub error location determination circuit corresponding to the second sub error value determination circuit 540-2 shown in FIG. 7A may output a second error value signal V₂ for the second symbol indicating

$$\frac{{S}_{1} {α}^{3} + {S}_{2}}{{α}^{2} + {α}^{3}}$$

and a second error value signal V₃ for the second symbol indicating

$$\frac{{S}_{1} {α}^{2} + {S}_{2}}{{α}^{2} + {α}^{3}} .$$

Referring back to FIG. 5, the error correction circuit 550 may correct the errors included in the data based on the locations of the errors and the values of the errors.

Referring to FIG. 5, the error location determination circuit 520 may provide the 0&1 to N−2&N−1 error flag signals e_{0,1}˜e_{N-2,N-1} to the error correction circuit 550. The error value determination circuit 540 may provide the 0th to N−1 error value signals v₀˜v_{N-1} to the error correction circuit 550.

In some embodiments, the error correction circuit 550 may correct the errors included in the data based on the locations of the errors and the values of the errors as shown in Equation 9 below.

$$\{ \begin{matrix}{R}_{i}^{c} = {R}_{i} , {R}_{i + 1}^{c} = {R}_{i + 1} ( if {e}_{i , i + 1} = 0 ) \\ {R}_{i}^{c} = {R}_{i} + {v}_{i} , {R}_{i + 1}^{c} = {R}_{i + 1} + {v}_{i + 1} ( if {e}_{i , i + 1} = 1 )\end{matrix} \qquad [ Equation 9 ]$$

Here, Rᵢ^{c} denotes the i-th symbol of the error-corrected codeword CCW, Rᵢ₊₁^{c} denotes the i+1 symbol of the error-corrected codeword CCW, Rᵢ denotes the i-th symbol of the read codeword RCW, Rᵢ₊₁ denotes the i+1 symbol of the read codeword RCW, e_{i,i+1} denotes the i&i+1 error flag signal, vᵢ denotes the error value of the i-th symbol, and vᵢ₊₁ denotes the error value of the i+1 symbol.

That is, the error correction circuit 550 may correct the i-th symbol and the i+1 symbol of the read codeword RCW according to the value of the i&i+1 error flag signal e_{i,i+1}.

When the value of the i&i+1 error flag signal e_{i,i+1} is 0, the error correction circuit 550 may output the i-th symbol and i+1 symbol of the read codeword RCW as the i-th symbol and the i+1 symbol of the error-corrected codeword CCW without correction.

When the value of the i&i+1 error flag signal e_{i,i+1} is 1, by adding the error value vᵢ of the i-th symbol to the i-th symbol of the read codeword RCW and adding the error value vᵢ₊₁ of the i+1 symbol to the i+1 symbol of the read codeword RCW, the error correction circuit 550 may output the i-th symbol and the i+1 symbol of the error-corrected codeword CCW.

The error correction circuit 550 may output an error-corrected codeword CCW based on the 0&1 to N−2&N−1 error flag signals e_{0,1}˜e_{N-2,N-1}, the 0th to N−1 error value signals v₀˜V_{N-1}, and the read codeword RCW.

Here, the data buffer 570 may receive the read codeword RCW, temporarily store the read codeword RCW, and provide the read codeword RCW to the error correction circuit 550.

That is, the error correction circuit 550 may correct the error of the read codeword RCW received from the data buffer 570 based on the 0&1 to N−2&N−1 error flag signals e_{0,1}˜e_{N-2,N-1} and the 0th to N−1 error value signal V₀˜V_{N-1}, and output the error-corrected codeword CCW.

The error correction circuit 550 may provide the error-corrected codeword CCW to the re-syndrome generation circuit 560.

The re-syndrome generation circuit 560 may receive the error-corrected codeword CCW and re-calculate syndromes for the error-corrected codeword CCW to determine whether the error correction operation is successful. The syndromes may be re-calculated using Equation 2 described above. For example, when the syndromes are S₁=S₂= . . . =S_{P}=0, the re-syndrome generation circuit 560 may determine that the error correction operation is successful.

When the error correction operation is successful, the re-syndrome generation circuit 560 may output the error-corrected codeword CCW to the outside. In addition, the re-syndrome generation circuit 560 may output, to the RS code decoder 320 (FIG. 3), the signal TERMINATION indicating termination of the error correction operation of the RS code decoder 320 (FIG. 3).

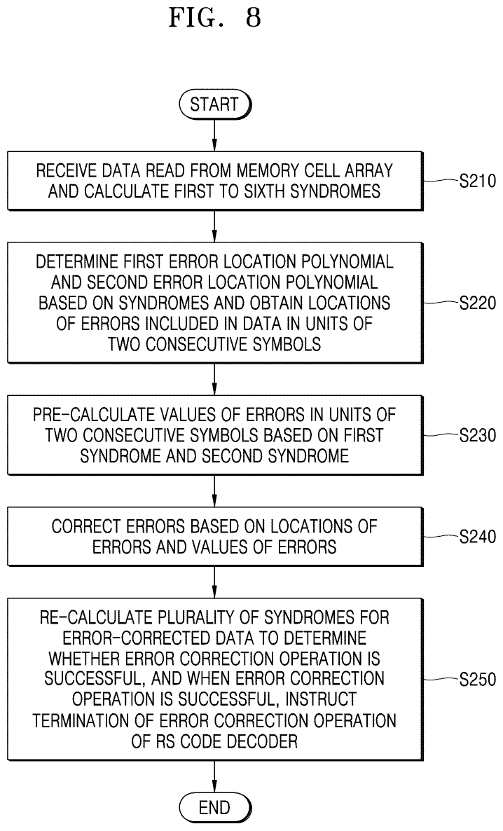

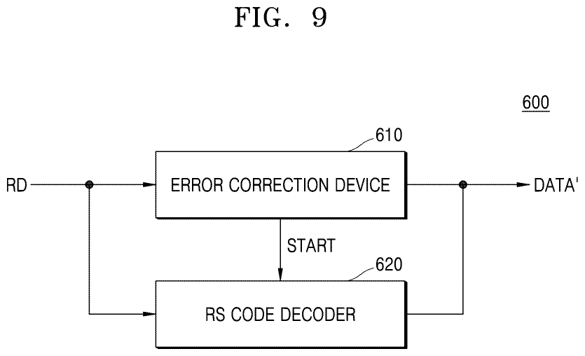

FIG. 8 is a flowchart illustrating an error correction method according to the decoder shown in FIG. 3. Hereinafter, FIG. 9 will be described with reference to FIGS. 3, 4A, 4B, 5, 6A, 6B, 6C,7A, and 7B, and redundant descriptions thereof will be omitted. The decoder 300 may include an error correction device 310 and an RS code decoder 320.

Referring to FIG. 8, in operation S210, the error correction device 310 may receive data read from a memory cell array and calculate first to sixth syndromes. Here, the error correction device 310 and the RS code decoder 320 may simultaneously start an error correction operation.

In addition, the first to sixth syndromes may be calculated by substituting powers of the primitive elements Q of the Galois field GF(2^{m}) into the reception polynomial R(x) based on the data, an exponent of the power of each of the primitive elements used to calculate the first to third syndromes may sequentially increase, and an exponent of the power of each of the primitive elements used to calculate the fourth to sixth syndromes may sequentially increase. For example, the exponent of the power of each of the primitive elements used to calculate the first to third syndromes may sequentially increase by 1, and the exponent of the power of each of the primitive elements used to calculate the fourth to sixth syndromes may sequentially increase by 1.

Operations S220 and S230 may simultaneously start, and are not limited to the precedence relationship shown in FIG. 8.

In operation S220, the error correction device 310 may determine a coefficient of a first error location polynomial based on the first to third syndromes, may determine a coefficient of a second error location polynomial based on the fourth to sixth syndromes, and may obtain locations of errors included in data in units of two consecutive symbols, based on the first error location polynomial and the second error location polynomial.

In operation S230, the error correction device 310 may pre-calculate values of errors that the data may have in units of two consecutive symbols, based on the first syndrome and the second syndrome.

In operation S240, the error correction device 310 may correct the errors included in the data based on the locations of the errors and the values of the errors.

In operation S250, the error correction device 310 may re-calculate a plurality of syndromes for the error-corrected data to determine whether an error correction operation is successful, and when the error correction operation is successful, may output the signal TERMINATION indicating termination of the error correction operation of the RS code decoder 320.

FIG. 9 is a block diagram illustrating another example of the decoder shown in FIG. 2.

Referring to FIG. 3, a decoder 600 may include an error correction device 610 and an RS code decoder 620. The error correction device 610 and the RS code decoder 620 may respectively correspond to the error correction device 310 and the RS code decoder 320 described with reference to FIG. 3, and redundant descriptions thereof will be omitted.

Unlike the error correction device 310 and the RS code decoder 320 described with reference to FIG. 3 performing the error correction operation in parallel, the error correction operation of the RS code decoder 620 may be performed only when the error correction operation of the error correction device 610 fails.

That is, when the error correction operation of the error correction device 610 fails, the error correction operation of the RS code decoder 620 may start.

Referring to FIG. 9, when the error correction operation of the error correction device 610 fails, the error correction device 610 may output, to the RS code decoder 620, a signal START indicating start of the error correction operation of the RS code decoder 620.

That is, when the error correction operation of the error correction device 610 is successful, the corrected data DATA′ may be output by the error correction device 610, and when the error correction operation of the error correction device 610 fails, the corrected data DATA′ may be output by the RS code decoder 620.

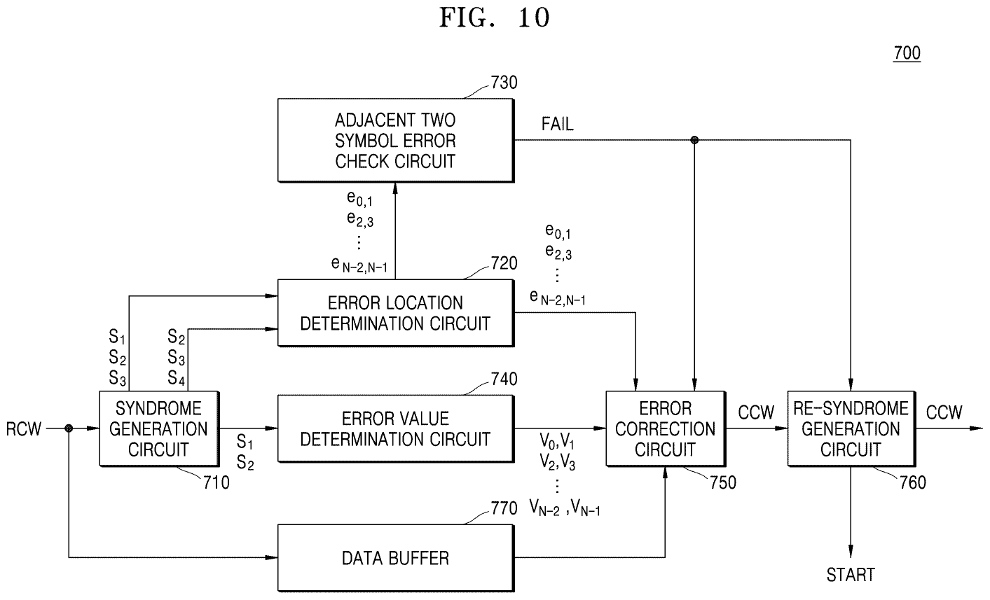

FIG. 10 is a block diagram illustrating an example of an error correction device shown in FIG. 9.

Referring to FIG. 10, an error correction device 700 may include a syndrome generation circuit 710, an error location determination circuit 720, an adjacent two-symbol error check circuit 730, an error value determination circuit 740, an error correction circuit 750, a re-syndrome generation circuit 760, and a data buffer 770.

The syndrome generation circuit 710, the error location determination circuit 720, the adjacent two-symbol error check circuit 730, the error value determination circuit 740, the error correction circuit 750, and the data buffer 770 described with reference to FIG. 5 may respectively correspond to the syndrome generation circuit 510, the error location determination circuit 520, the adjacent two-symbol error check circuit 530, the error value determination circuit 540, the error correction circuit 550 and the data buffer 570, and redundant descriptions thereof will be omitted.

That is, operations of the re-syndrome generation circuit 560 shown in FIG. 5 and the re-syndrome generation circuit 760 shown in FIG. 10 are different from each other, and thus, the re-syndrome generation circuit 760 will be described.

The re-syndrome generation circuit 760 may receive the error-corrected codeword CCW and re-calculate syndromes for the error-corrected codeword CCW to determine whether an error correction operation is successful. The syndromes may be re-calculated using Equation 2 described above. For example, when the syndromes are S₁=S₂= . . . =S_{P}=0, the re-syndrome generation circuit 760 may determine that the error correction operation is successful. When the syndromes are not S₁=S₂= . . . =S_{P}=0, the re-syndrome generation circuit 760 may determine that the error correction operation fails. In addition, when the re-syndrome generation circuit 760 receives the fail signal FAIL of the adjacent two-symbol error check circuit 730, the re-syndrome generation circuit 760 may determine that the error correction operation fails.

When the error correction operation is successful, the re-syndrome generation circuit 560 may output the error-corrected codeword CCW to the outside.

When the error correction operation fails, the re-syndrome generation circuit 560 may output, to the RS code decoder 620 (FIG. 9), the signal START indicating the start of the error correction operation of the RS code decoder 620 (FIG. 9).

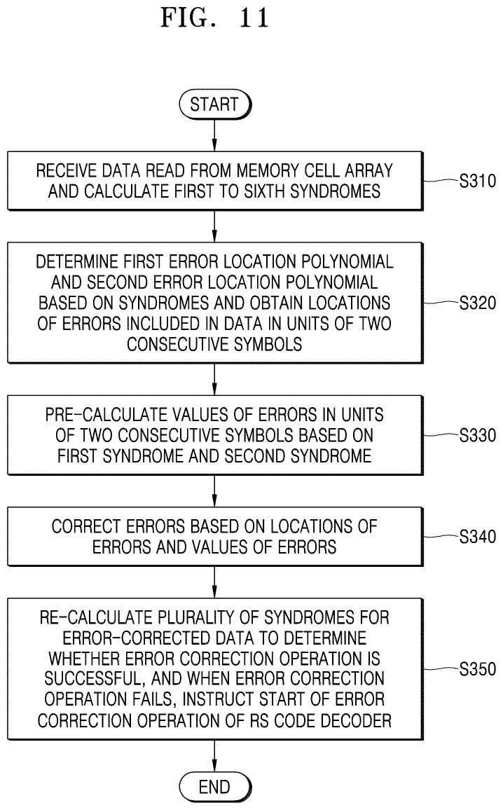

FIG. 11 is a flowchart illustrating an error correction method according to a decoder shown in FIG. 9. Hereinafter, FIG. 11 will be described with reference to FIGS. 9 to 10, and redundant descriptions thereof will be omitted. The decoder 600 may include the error correction device 610 and the RS code decoder 620.

Referring to FIG. 11, in operation S310, the error correction device 610 may receive data read from a memory cell array and calculate first to sixth syndromes. In addition, the first to sixth syndromes may be calculated by substituting powers of the primitive elements a of the Galois field GF(2^{m}) into the reception polynomial R(x) based on the data, an exponent of the power of each of the primitive elements used to calculate the first to third syndromes may sequentially increase, and an exponent of the power of each of the primitive elements used to calculate the fourth to sixth syndromes may sequentially increase. For example, the exponent of the power of each of the primitive elements used to calculate the first to third syndromes may sequentially increase by 1, and the exponent of the power of each of the primitive elements used to calculate the fourth to sixth syndromes may sequentially increase by 1.

Operations S320 and S330 may simultaneously start, and are not limited to the precedence relationship shown in FIG. 8.

In operation S320, the error correction device 610 may determine a coefficient of a first error location polynomial based on the first to third syndromes, may determine a coefficient of a second error location polynomial based on the fourth to sixth syndromes, and may obtain locations of errors included in data in units of two consecutive symbols, based on the first error location polynomial and the second error location polynomial.

In operation 5330, the error correction device 610 may pre-calculate values of errors that the data may have in units of two consecutive symbols, based on the first syndrome and the second syndrome.

In operation 5340, the error correction device 610 may correct the errors included in the data based on the locations of the errors and the values of the errors.

In operation 5350, the error correction device 610 may re-calculate a plurality of syndromes for the error-corrected data to determine whether an error correction operation is successful, and, when the error correction operation is successful, may output the signal START indicating the start of the error correction operation of the RS code decoder 620.

Here, the RS code decoder 620 may start the error correction operation in response to the signal START instructing the start of the error correction operation.

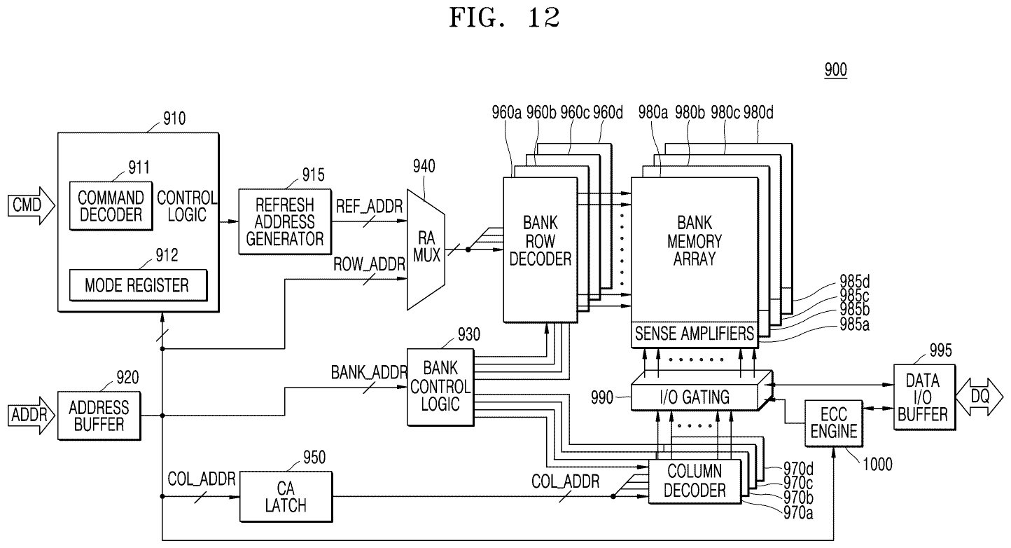

FIG. 12 is a diagram illustrating a memory device according to some embodiments.

Referring to FIG. 12, a memory device 900 may include a control logic 910, a refresh address generator 915, an address buffer 920, a bank control logic 930, a row address multiplexer 940, a column address (CA) latch 950, a row decoder, a memory cell array, a sense amplification unit, an input/output (I/O) gating circuit 990, a data I/O buffer 995, and an ECC engine 1000.

The memory cell array may include first, second, third, and fourth bank arrays 980a, 980b, 980c, and 980d. The row decoder may include first, second, third, and fourth bank row decoders 960a, 960b, 960c, and 960d respectively connected to the first, second, third, and fourth bank arrays 980a, 980b, 980c, and 980d. The column decoder may include first, second, third, and fourth bank column decoders 970a, 970b, 970c, and 970d respectively connected to the first, second, third, and fourth bank arrays 980a, 980b, 980c, and 980d. The sense amplification unit may include first, second, third, and fourth bank sense amplifiers 985a, 985b, 985c, and 985d respectively connected to the first, second, third, and fourth bank arrays 980a, 980b, 980c, and 985d. The first, second, third, and fourth bank arrays 980a, 980b, 980c, and 980d, the first, second, third, and fourth bank row decoders 960a, 960b, 960c, and 960d, the first, second, third, and fourth bank column decoders 970a, 970b, 970c, and 970d, and the first, second, third, and fourth bank sense amplifiers 985a, 985b, 985c, and 985d may respectively constitute first, second, third, and fourth banks. An example of the memory device 900 including four banks is shown in FIG. 9, but according to some embodiments, the memory device 900 may include any number of banks.

In addition, according to some embodiments, the memory device 900 may be dynamic random access memory (DRAM) such as Double Data Rate Synchronous Dynamic Random Access Memory (DDR SDRAM), Low Power Double Data Rate (LPDDR), Graphics Double Data Rate (GDDR) SDRAM, or Rambus Dynamic Random Access Memory (RDRAM) or any volatile memory device that requires a refresh operation.

The control logic 910 may control operations of the memory device 900. For example, the control logic 910 may generate control signals for the memory device 900 to perform a write operation or a read operation. The control logic 910 may include a command decoder 911 decoding a command CMD received from a memory controller and a mode register 912 setting an operation mode of the memory device 900. For example, the command decoder 911 may decode a write enable signal/WE, a row address strobe signal/RAS, a column address strobe signal/CAS, and a chip selection signal/CS to generate control signals corresponding to the command CMD.

The control logic 910 may further receive a clock CLK and a clock enable signal CKE for driving the memory device 900 in a synchronous manner. The control logic 910 may control the refresh address generator 915 to perform an auto refresh operation in response to a refresh command, or control the refresh address generator 915 to perform a self-refresh operation in response to a self-refresh entry command.

The refresh address generator 915 may generate a refresh address REF_ADDR corresponding to a memory cell row in which the refresh operation is to be performed. The refresh address generator 915 may generate a refresh address REF_ADDR at a refresh rate of a period longer than a refresh period defined in the standard or conventional parameters of the memory device 900. Accordingly, refresh current and refresh power of the memory device 900 may be reduced.

The address buffer 920 may receive an address ADDR including a bank address BANK_ADDR, a row address ROW_ADDR, and a column address COL_ADDR from the memory controller. In addition, the address buffer 920 may provide the received bank address BANK_ADDR to the bank control logic 930, provide the received row address ROW_ADDR to the row address multiplexer 940, and provide the received column address COL_ADDR to the column address latch 950.

The bank control logic 930 may generate bank control signals in response to the bank address BANK_ADDR. In response to the bank control signals, a bank row decoder corresponding to the bank address BANK_ADDR among the first, second, third, and fourth bank row decoders 960a, 960b, 960c, and 960d may be activated, and a bank column decoder corresponding to the bank address BANK_ADDR among the first, second, third, and fourth bank column decoders 970a, 970b, 970c, and 970d may be activated.

The bank control logic 930 may generate bank group control signals in response to the bank address BANK_ADDR determining a bank group. In response to the bank group control signals, row decoders of a bank group corresponding to the bank address BANK_ADDR among the first, second, third, and fourth bank row decoders 960a, 960b, 960c, and 960d may be activated, and column decoders of a bank group corresponding to the bank address BANK_ADDR among the first, second, third, and fourth bank column decoders 970a, 970b, 970c, and 970d may be activated.

The row address multiplexer 940 may receive the row address ROW_ADDR from the address buffer 920 and the refresh row address REF_ADDR from the refresh address generator 915. The row address multiplexer 940 may selectively output the row address ROW_ADDR or the refresh row address REF_ADDR. The row address ROW_ADDR output from the row address multiplexer 940 may be applied to each of the first, second, third, and fourth bank row decoders 960a, 960b, 960c, and 960d.

The bank row decoder activated by the bank control logic 930 among the first, second, third, and fourth bank row decoders 960a, 960b, 960c, and 960d may decode the row address ROW_ADDR output from the row address multiplexer 940 to activate a word line corresponding to the row address ROW_ADDR. For example, the activated bank row decoder may apply a word line driving voltage to the word line corresponding to the row address ROW_ADDR.

The column address latch 950 may receive the column address COL_ADDR from the address buffer 920 and temporarily store the received column address COL_ADDR. The column address latch 950 may gradually increase the column address COL_ADDR received in a burst mode. The column address latch 950 may apply the temporarily stored or gradually increased column address COL_ADDR to each of the first to fourth bank column decoders 970a, 970b, 970c, and 970d.

The bank column decoder activated by the bank control logic 930 among the first to fourth bank column decoders 970a, 970b, 970c, and 970d may activate a sense amplifier corresponding to the bank address BANK_ADDR and the column address COL_ADDR through the input/output gating circuit 990.

The input/output gating circuit 990 may include an input data mask logic, read data latches storing data output from the first, second, third, and fourth bank arrays 980a, 980b, 980c, and 980d, and a write driver writing data to the first, second, third, and fourth bank arrays 980a, 980b, 980c, and 980d, along with circuits gating input/output data.

Data DQ to be read from one of the first to fourth bank arrays 980a, 980b, 980c, and 980d may be sensed and amplified by the sense amplifier and stored in the read data latches. The data DQ stored in the read data latches may be provided to the memory controller through the data input/output buffer 995. The data DQ to be written in one of the first to fourth bank arrays 980a, 980b, 980c, and 980d may be provided from the memory controller to the data input/output buffer 995. The data DQ provided to the data input/output buffer 995 may be written to one bank array through the write driver.

The ECC engine 1000 may correspond to the decoders 100, 300, and 600 shown in FIGS. 1 to 11. The ECC engine 1000 may include the error correction device 310, 500, 610, or 700 shown in FIGS. 1 to 11. The ECC engine 1000 may reduce the latency required by performing an error correction operation on two consecutive symbols.

In addition, FIG. 12 shows that the ECC engine 1000 is included in the memory device 900, but the ECC engine 1000 is not limited thereto, and may be included in the memory controller.

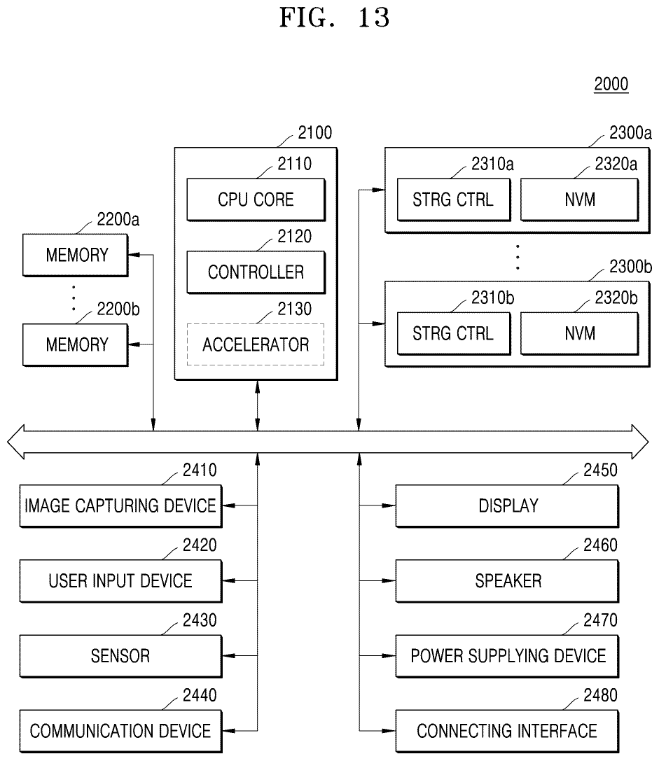

FIG. 13 is a diagram illustrating a system to which a storage device is applied, according to some embodiments.

Referring to FIG. 13, a system 2000 of FIG. 13 may basically be a mobile system such as a mobile phone, a smart phone, a tablet personal computer (PC), a wearable device, a healthcare device, or an Internet of things (IOT) device. However, the system 2000 of FIG. 13 is not necessarily limited to a mobile system, and may be a personal computer, a laptop computer, a server, a media player, or an automotive device such as navigation.

Referring to FIG. 13, the system 2000 may include a main processor 2100, memories 2200a and 2200b, and storage devices 2300a and 2300b, and may further include one or more of an image capturing device 2410, a user input device 2420, a sensor 2430, a communication device 2440, a display 2450, a speaker 2460, a power supplying device 2470, and a connecting interface 2480.

The main processor 2100 may control the overall operations of the system 2000, more specifically, operations of other components included in the system 2000. The main processor 2100 may be implemented as a general-purpose processor, a dedicated processor, or an application processor.

The main processor 2100 may include one or more CPU cores 2110, and may further include a controller 2120 for controlling the memories 2200a and 2200b and/or the storage devices 2300a and 2300b. According to some embodiments, the main processor 2100 may further include an accelerator 2130, which is a dedicated circuit for high-speed data operation such as an artificial intelligence (AI) data operation. Such an accelerator 2130 may include a graphics processing unit (GPU), a natural processing unit (NPU), and/or a data processing unit (DPU), and may be implemented as a separate chip physically independent of other components of the main processor 2100.

The memories 2200a and 2200b may be used as main memory devices of the system 2000, may include volatile memories such as SRAM and/or DRAM, but may include nonvolatile memories such as flash memory, PRAM and/or RRAM. The memories 2200a and 2200b may be implemented in the same package as the main processor 2100.

The storage devices 2300a and 2300b may function as nonvolatile storage devices that store data regardless of whether power is supplied, and may have a relatively large storage capacity compared to the memories 2200a and 2200b. The storage devices 2300a and 2300b may include storage controllers 2310a and 2310b and nonvolatile memories (NVMs) 2320a and 2320b that store data by the control of the storage controllers 2310a and 2310b. The NVMs 2320a and 2320b may each include flash memory of a 2-dimensional (2D) structure or a 3-dimensional (3D) vertical NAND (V-NAND) structure, but may include other types of NVMs such as PRAM and/or RRAM.

The storage devices 2300a and 2300b may be included in the system 2000 while being physically separated from the main processor 2100, or may be implemented in the same package as the main processor 2100. In addition, the storage devices 2300a and 2300b may have a form such as a solid state device (SSD) or a memory card so as to be detachably combined with other components of the system 2000 through an interface such as the connecting interface 2480 to be described below. Such storage devices 2300a and 2300b may be devices to which standard conventions such as universal flash storage (UFS), embedded multi-media card (eMMC), or non-volatile memory express (NVMe) are applied, but are not limited thereto.

The image capturing device 2410 may capture a still image or a moving image, and may be a camera, a camcorder, and/or a webcam.

The user input device 2420 may receive various types of data input from a user of the system 2000, and may be a touch pad, a keypad, a keyboard, a mouse, and/or a microphone.

The sensor 2430 may detect various types of physical quantities that may be obtained from the outside of the system 2000, and convert the detected physical quantities into electrical signals.

The sensor 2430 may be a temperature sensor, a pressure sensor, an illuminance sensor, a location sensor, an acceleration sensor, a biosensor, and/or a gyroscope sensor.

The communication device 2440 may transmit and receive signals with other devices outside the system 2000 according to various communication protocols. The communication device 2440 may be implemented by including an antenna, a transceiver, and/or a modem (MODEM).

The display 2450 and the speaker 2460 may function as output devices that respectively output visual information and auditory information to the user of the system 2000.

The power supplying device 2470 may appropriately convert power supplied from a battery (not shown) and/or an external power source embedded in or connected to the system 2000 and supply the power to each of the components of the system 2000.

The connecting interface 2480 may provide a connection between the system 2000 and an external device connected to the system 2000 and capable of transmitting and receiving data to and from the system 2000. The connecting interface 2480 may be implemented in various interface methods such as Advanced Technology Attachment (ATA), Serial ATA (SATA), external SATA (e-SATA), Small Computer Small Interface (SCSI), Serial Attached SCSI (SAS), Peripheral Component Interconnection (PCI), PCI express (PCIe), NVMe, IEEE 1394, universal serial bus (USB), secure digital (SD) card, multi-media card (MMC), eMMC, UFS, embedded UFS (eUFS), and compact flash (CF) card interfaces.

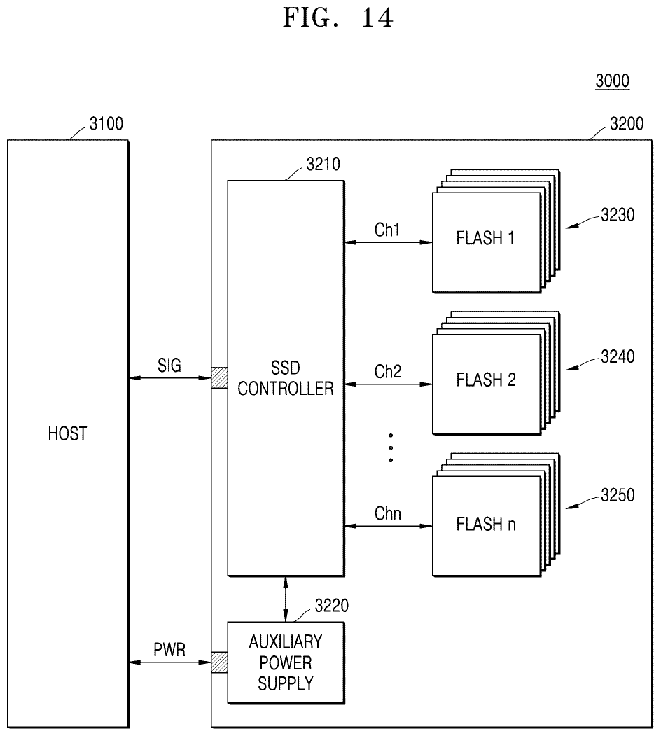

FIG. 14 is a block diagram illustrating an example in which a memory controller is applied to an SSD system according to some embodiments.

Referring to FIG. 14, an SSD system 3000 may include a host 3100 and an SSD 3200. The SSD 3200 may transmit and receive signals to and from the host 3100 through a signal connector, and may receive power through a power connector. The SSD 3200 may include an SSD controller 3210, an auxiliary power supply 3220, and memory devices 3230, 3240, and 3250. At this time, the SSD 3200 may be implemented using the embodiments described above with reference to FIGS. 1, 2, 3, 4A, 4B, 5, 6A, 6B, 6C, 7A, 7B, 8, 9, 10, 11, 12, and 13.

While the inventive concept has been particularly shown and described with reference to embodiments thereof, it will be understood that various changes in form and details may be made therein without departing from the spirit and scope of the following claims.

What is claimed is:

1. An error correction device comprising:
a syndrome generation circuit configured to receive data and output a first syndrome, a second syndrome, a third syndrome, a fourth syndrome, a fifth syndrome, and a sixth syndrome for the data that are determined by substituting powers of primitive elements of a Galois field into a reception polynomial based on the data, wherein respective exponents of the powers of respective ones of the primitive elements used to determine the first syndrome, the second syndrome, and the third syndrome sequentially increase, and wherein respective exponents of the powers of respective ones of the primitive elements used to determine the fourth syndrome, the fifth syndrome, and the sixth syndrome sequentially increase;
an error location determination circuit configured to determine a coefficient of a first error location polynomial based on the first syndrome, the second syndrome, and the third syndrome, determine a coefficient of a second error location polynomial based on the fourth syndrome, the fifth syndrome, and the sixth syndrome, and obtain locations of errors included in the data in units of two consecutive symbols based on the first error location polynomial and the second error location polynomial;
an error value determination circuit configured to predetermine values of the errors in units of two consecutive symbols, based on the first syndrome and the second syndrome; and
an error correction circuit configured to correct the errors included in the data, based on the locations of the errors and the values of the errors.

2. The error correction device of claim 1,
wherein the error location determination circuit is configured to determine the first error location polynomial based on equation
$${Λ}_{1} ( {α}^{i} ) = {S}_{d} ( α * {α}^{2 i} ) + {S}_{d + 1} ( α + 1 ) {α}^{i} + {S}_{d + 2}$$
and determine the second error location polynomial based on equation
$${Λ}_{2} ( {α}^{i} ) = {S}_{f} ( α * {α}^{2 i} ) + {S}_{f + 1} ( α + 1 ) {α}^{i} + {S}_{f + 2} ,$$
wherein α denotes the primitive element of the Galois field, Λ₁(αⁱ) denotes the first error location polynomial, Λ₂(αⁱ) denotes the second error location polynomial, S_{d} denotes the first syndrome, S_{d+1} denotes the second syndrome, S_{d+2} denotes the third syndrome, S_{f} denotes the fourth syndrome, S_{f+1} denotes the fifth syndrome, S_{f+2} denotes the sixth syndrome, and d and f are positive integers and are different from each other.

3. The error correction device of claim 1,
wherein the second syndrome is same as the fourth syndrome,
wherein the third syndrome is same as the fifth syndrome, and
wherein the respective exponents of the powers of respective ones of the primitive elements used to determine the first syndrome, the second syndrome, the third syndrome, and the sixth syndrome sequentially increase.

4. The error correction device of claim 3,
wherein the error location determination circuit is configured to determine the first error location polynomial based on equation
$${Λ}_{1} ( {α}^{i} ) = {S}_{1} ( α * {α}^{2 i} ) + {S}_{2} ( α + 1 ) {α}^{i} + {S}_{3}$$
and determine the second error location polynomial based on equation
$${Λ}_{2} ( {α}^{i} ) = {S}_{2} ( α * {α}^{2 i} ) + {S}_{3} ( α + 1 ) {α}^{i} + {S}_{4} ,$$
wherein α denotes the primitive element of the Galois field, Λ₁(αⁱ) denotes the first error location polynomial, Λ₂(αⁱ) denotes the second error location polynomial, S₁ denotes the first syndrome, S₂ denotes the second syndrome, S₃ denotes the third syndrome, and S₄ denotes the sixth syndrome.

5. The error correction device of claim 1,
wherein the first error location polynomial and the second error location polynomial are polynomials relating to a power of the primitive element of the Galois field of the powers of the primitive elements having an exponent i of the respective exponents of the powers,
wherein the error location determination circuit is configured to output an error flag signal indicating errors in an i-th symbol and an i+1 symbol when the primitive element having the exponent determines that a value of the first error location polynomial and a value of the second error location polynomial are 0.

6. The error correction device of claim 1, further comprising:
a re-syndrome generation circuit configured to receive error-corrected data, determine a plurality of syndromes for the error-corrected data to determine whether an error correction operation is successful, and output a signal indicating termination of the error correction operation of a Reed-Solomon (RS) code decoder when the error correction operation is successful.

7. The error correction device of claim 1, further comprising:
a re-syndrome generation circuit configured to receive error-corrected data, determine a plurality of syndromes for the error-corrected data to determine whether an error correction operation is successful, and output a signal indicating start of the error correction operation of a Reed-Solomon (RS) code decoder when the error correction operation fails.

8. A memory system comprising:
a memory device comprising a plurality of memory cells; and
a memory controller configured to correct data that has been read from the memory device,
wherein the memory controller comprises:
an error correction device, wherein the error correction device comprises a syndrome generation circuit configured to receive data and output a first syndrome, a second syndrome, a third syndrome, a fourth syndrome, a fifth syndrome, and a sixth syndrome for the data, that are determined by substituting powers of primitive elements of a Galois field into a reception polynomial based on the data, wherein respective exponents of the powers of respective ones of the primitive elements used to determine the first syndrome, the second syndrome, and the third syndrome sequentially increase, and wherein respective exponents of the power of respective ones of the primitive elements used to determine the fourth syndrome, the fifth syndrome, and the sixth syndrome sequentially increase;
an error location determination circuit configured to determine a coefficient of a first error location polynomial based on the first syndrome, the second syndrome, and the third syndrome, determine a coefficient of a second error location polynomial based on the fourth syndrome, the fifth syndrome, and the sixth syndrome, and obtain locations of errors included in the data in units of two consecutive symbols based on the first error location polynomial and the second error location polynomial;
an error value determination circuit configured to predetermine values of the errors in units of two consecutive symbols, based on the first syndrome and the second syndrome; and
an error correction circuit configured to correct the errors included in the data, based on the locations of the errors and the values of the errors.

9. The memory system of claim 8,
wherein the error location determination circuit is configured to determine the first error location polynomial based on equation
$${Λ}_{1} ( {α}^{i} ) = {S}_{d} ( α * {α}^{2 i} ) + {S}_{d + 1} ( α + 1 ) {α}^{i} + {S}_{d + 2}$$
and determine the second error location polynomial based on equation
$${Λ}_{2} ( {α}^{i} ) = {S}_{f} ( α * {α}^{2 i} ) + {S}_{f + 1} ( α + 1 ) {α}^{i} + {S}_{f + 2} ,$$
wherein α denotes the primitive element of the Galois field, Λ₁(αⁱ) denotes the first error location polynomial, Λ₂(αⁱ) denotes the second error location polynomial, S_{d} denotes the first syndrome, S_{d+1} denotes the second syndrome, S_{d+2} denotes the third syndrome, S_{f} denotes the fourth syndrome, S_{f+1} denotes the fifth syndrome, S_{f+2} denotes the sixth syndrome, and d and f are positive integers and are different from each other.

10. The memory system of claim 8,
wherein the second syndrome is same as the fourth syndrome,
wherein the third syndrome is same as the fifth syndrome, and
wherein the respective exponents of the powers of respective ones of the primitive elements used to determine the first syndrome, the second syndrome, the third syndrome, and the sixth syndrome sequentially increase.

11. The memory system of claim 10,
wherein the error location determination circuit is configured to determine the first error location polynomial based on equation
$${Λ}_{1} ( {α}^{i} ) = {S}_{1} ( α * {α}^{2 i} ) + {S}_{2} ( α + 1 ) {α}^{i} + {S}_{3}$$
and determine the second error location polynomial based on equation
$${Λ}_{2} ( {α}^{i} ) = {S}_{2} ( α * {α}^{2 i} ) + {S}_{3} ( α + 1 ) {α}^{i} + {S}_{4} ,$$
wherein α denotes the primitive element of the Galois field, Λ₁(αⁱ) denotes the first error location polynomial, Λ₂(αⁱ) denotes the second error location polynomial, S₁ denotes the first syndrome, S₂ denotes the second syndrome, S₃ denotes the third syndrome, and S₄ denotes the sixth syndrome.

12. The memory system of claim 8,
wherein the first error location polynomial and the second error location polynomial are polynomials relating to a power of the primitive element of the powers of the primitive elements of the Galois field having an exponent i of the respective exponents of the powers,
wherein the error location determination circuit is configured to output an error flag signal indicating errors in an i-th symbol and an i+1 symbol” when the primitive element having the exponent determines that a value of the first error location polynomial and a value of the second error location polynomial are 0.

13. The memory system of claim 8,
wherein the memory controller further includes a Reed-Solomon (RS) code decoder, and
wherein the error correction device further comprises a re-syndrome generation circuit configured to receive error-corrected data, determine a plurality of syndromes for the error-corrected data to determine whether an error correction operation is successful, and output a signal indicating termination of the error correction operation of the RS code decoder when the error correction operation is successful.

14. The memory system of claim 8,
wherein the memory controller further comprises a Reed-Solomon (RS) code decoder, and
wherein the error correction device further comprises a re-syndrome generation circuit configured to receive error-corrected data, determine a plurality of syndromes for the error-corrected data to determine whether an error correction operation is successful, and output a signal indicating start of the error correction operation of an RS code decoder when the error correction operation fails.

15. An error correction method comprising:
receiving data and outputting a first syndrome, a second syndrome, a third syndrome, a fourth syndrome, a fifth syndrome, and a sixth syndrome for the data that are determined by substituting powers of primitive elements of a Galois field into a reception polynomial based on the data, wherein respective exponents of the powers of respective ones of the primitive elements used to determine the first syndrome, the second syndrome, and the third syndrome sequentially increase, and wherein respective exponents of the power of respective ones of the primitive elements used to determine the fourth syndrome, the fifth syndrome, and the sixth syndrome sequentially increase;
determining a coefficient of a first error location polynomial based on the first syndrome, the second syndrome, and the third syndrome, determining a coefficient of a second error location polynomial based on the fourth syndrome, the fifth syndrome, and the sixth syndrome, and obtaining locations of errors included in the data in units of two consecutive symbols based on the first error location polynomial and the second error location polynomial;
predetermining values of the errors in units of two consecutive symbols, based on the first syndrome and the second syndrome; and
correcting the errors included in the data, based on the locations of the errors and the values of the errors.

16. The error correction method of claim 15,
wherein the first error location polynomial is determined based on equation
$${Λ}_{1} ( {α}^{i} ) = {S}_{d} ( α * {α}^{2 i} ) + {S}_{d + 1} ( α + 1 ) {α}^{i} + {S}_{d + 2}$$
and the second error location polynomial is determined based on equation
$${Λ}_{2} ( {α}^{i} ) = {S}_{f} ( α * {α}^{2 i} ) + {S}_{f + 1} ( α + 1 ) {α}^{i} + {S}_{f + 2} ,$$
wherein α denotes the primitive element of the Galois field, Λ₁(αⁱ) denotes the first error location polynomial, Λ₂(αⁱ) denotes the second error location polynomial, S_{d} denotes the first syndrome, S_{d+1} denotes the second syndrome, S_{d+2} denotes the third syndrome, S_{f} denotes the fourth syndrome, S_{f+1} denotes the fifth syndrome, S_{f+2} denotes the sixth syndrome, and d and f are positive integers and are different from each other.

17. The error correction method of claim 15,
wherein the second syndrome is same as the fourth syndrome,
wherein the third syndrome is same as the fifth syndrome, and
wherein the respective exponents of the powers of respective ones of the primitive elements used to determine the first syndrome, the second syndrome, the third syndrome, and the sixth syndrome sequentially increase.

18. The error correction method of claim 17,
wherein the first error location polynomial is determined based on equation
$${Λ}_{1} ( {α}^{i} ) = {S}_{1} ( α * {α}^{2 i} ) + {S}_{2} ( α + 1 ) {α}^{i} + {S}_{3}$$
and the second error location polynomial is determined based on equation
$${Λ}_{2} ( {α}^{i} ) = {S}_{2} ( α * {α}^{2 i} ) + {S}_{3} ( α + 1 ) {α}^{i} + {S}_{4} ,$$
wherein α denotes the primitive element of the Galois field, Λ₁(αⁱ) denotes the first error location polynomial, Λ₂(αⁱ) denotes the second error location polynomial, S₁ denotes the first syndrome, S₂ denotes the second syndrome, S₃ denotes the third syndrome, and S₄ denotes the sixth syndrome.

19. The error correction method of claim 15,
wherein the first error location polynomial and the second error location polynomial are polynomials relating to a power of the primitive element of the powers of the primitive elements of the Galois field having an exponent i of the respective exponents of the powers,
wherein the obtaining of the locations of the errors includes outputting an error flag signal indicating errors in an i-th symbol and an i+1 symbol when the primitive element having the exponent determines that a value of the first error location polynomial and a value of the second error location polynomial are 0.

20. The error correction method of claim 15, further comprising:
receiving error-corrected data, calculating a plurality of syndromes for the error-corrected data to determine whether an error correction operation is successful, and outputting a signal indicating termination of the error correction operation of a Reed-Solomon (RS) code decoder when the error correction operation is successful.
